(19) United States
(12) Patent Application Publication
(10) Pub. No.: US 2011/0101302 A1
(43) Pub. Date: May 5, 2011

(54) WAFER-SCALE FABRICATION OF SEPARATED CARBON NANOTUBE THIN-FILM TRANSISTORS

(75) Inventors: Chongwu Zhou, Arcadia, CA (US); Chuan Wang, Los Angeles, CA (US); Jialu Zhang, Los Angeles, CA (US); Koungmin Ryu, Los Angeles, CA (US); Alexander Badmaev, Pasadena, CA (US); Lewis Gomez De Arco, Los Angeles, CA (US)

(73) Assignee: UNIVERSITY OF SOUTHERN CALIFORNIA, Los Angeles, CA (US)

(21) Appl. No.: 12/940,674

(22) Filed: Nov. 5, 2010

Related U.S. Application Data
(60) Provisional application No. 61/258,562, filed on Nov. 5, 2009.

(51) Int. Cl. H01L 29/775; H01L 21/20; H01L 21/84; H01L 51/52; B82Y 40/00; B82Y 99/00

(52) U.S. Cl. 257/13; 438/479; 438/151; 438/34; 438/156; 257/24; 257/E51.018; 257/E29.003; 257/E21.09; 257/E21.704; 977/936; 977/952; 257/E29.245

(57) ABSTRACT

Methods, materials, systems and apparatus are described for depositing a separated nanotube networks, and fabricating, separated nanotube thin-film transistors and N-type separated nanotube thin-film transistors. In one aspect, a method of depositing a wafer-scale separated nanotube networks includes providing a substrate with a dielectric layer. The method includes cleaning a surface of the wafer substrate to cause the surface to become hydrophilic. The cleaned surface of the wafer substrate is functionalized by applying a solution that includes linker molecules terminated with amine groups. High density, uniform separated nanotubes are assembled over the functionalized surface by applying to the functionalized surface a separated nanotube solution that includes semiconducting nanotubes.

### PRIORITY CLAIM

This application claims priority under 35 U.S.C. §119(e) to the Provisional Patent Application No. 61/258,562 entitled “WAFER-SCALE FABRICATION OF SEPARATED CARBON NANOTUBE THIN-FILM TRANSISTORS” filed Nov. 5, 2009, the entire contents of which are incorporated by reference.

### GOVERNMENT SUPPORT

This invention was made with government support under grant number CCF-0726815 and CCF-0702204 awarded by National Science Foundation. The government has certain rights in the invention.

### BACKGROUND

This application relates to semiconductor devices.

Thin-film transistors (TFTs) can be implemented in various applications including display devices. Amorphous silicon has been widely used as the channel material for TFTs. Also, other materials, such as organic TFTs and single-walled carbon nanotubes (SWNTs) have been used.

### SUMMARY

Techniques, systems and apparatus are disclosed for implementing wafer-scale fabrication of separated nanotube thin-film transistors and N-type separated nanotube thin-film transistors.

In one aspect, a method of fabricating a wafer-scale separated semiconducting nanotube network includes providing a wafer substrate and a dielectric layer disposed over the substrate. The cleaned surface of the wafer substrate is functionalized by applying a solution comprising linker molecules terminated with amine groups. Separated nanotubes is assembled over the functionalized surface by applying to the functionalized surface a separated nanotube solution that includes semiconducting nanotubes. Residual materials are removed from the assembled separated nanotubes.

Implementations can optionally include one or more of the following features. The substrate can include silicon, glass, or polyethylene terephthalate (PET). The dielectric layer can include various dielectric materials such as SiO₂, Al₂O₃, or HfO₂. The linker molecules terminated with amine groups can include aminopropyltriethoxy silane (APTES) or other similar linker molecules.

In another aspect, a method of fabricating a separated semiconducting nanotube thin-film transistor device, include fabricating a wafer-scale separated semiconducting nanotube network, which includes providing a wafer substrate and a gate dielectric layer disposed over the substrate. Fabricating a wafer-scale separated semiconducting nanotube network includes cleaning a surface of the wafer substrate to cause the surface to become hydrophilic. Fabricating a wafer-scale separated semiconducting nanotube network includes functionalizing the cleaned surface of the wafer substrate by applying a solution comprising linker molecules terminated with amine groups. Fabricating a wafer-scale separated semiconducting nanotube network includes assembling separated nanotubes over the functionalized surface by applying to the functionalized surface a separated nanotube solution that includes semiconducting nanotubes, and removing residual materials from the assembled separated nanotubes. Fabricating a separated semiconducting nanotube thin-film transistor device includes fabricating a transistor device using the wafer-scale semiconducting separated nanotube network, which includes forming source and drain electrodes on the wafer substrate having the wafer-scale semiconducting separated nanotube network. Fabricating a transistor device using the wafer-scale semiconducting separated nanotube network includes forming source and drain metal contacts on the wafer substrate having the wafer-scale separated semiconducting nanotube network, and removing unwanted separated nanotubes from the wafer substrate that are outside a channel region.

Implementations can optionally include one or more of the following features. The substrate can include silicon, glass, or polyethylene terephthalate (PET). The gate dielectric layer can include SiO₂, Al₂O₃, or HfO₂. The linker molecules terminated with amine groups can include aminopropyltriethoxy silane (APTES). Forming the source and drain electrodes can include patterned the source and drain electrodes by photo-lithography. Forming the source and drain metal contacts can include forming the source and drain metal contacts by depositing metal followed by a lift-off process. Removing the unwanted separated nanotubes can include using photo-lithography and O₂ plasma to remove the unwanted separated nanotubes outside the channel region.

The described methods can be used to implement a separated semiconducting nanotube thin-film transistor device, which can include a wafer substrate and a gate dielectric layer. A surface of the wafer substrate is hydrophilic and functionalized with linker molecules terminated with amine groups. The separated semiconducting nanotube thin-film transistor device can include a network of separated nanotubes disposed over the functionalized surface of the substrate. The network of separated nanotubes can include semiconducting nanotubes; source and drain electrodes formed on the wafer substrate; and source and drain metal contacts formed on the wafer substrate.

Implementations can optionally include one or more of the following features. The substrate can include silicon, glass, or polyethylene terephthalate (PET). The gate dielectric layer can include SiO₂, Al₂O₃, or HfO₂. The linker molecules terminated with amine groups can include aminopropyltriethoxy silane (APTES). The network of the separated nanotubes covers the surface of the substrate except for an area outside a channel region.

In yet another aspect, the methods described herein can be used to implement a display system, which includes a display control circuit that includes a separated semiconducting nanotube thin-film transistor device. The separated semiconducting nanotube thin-film transistor device can include a wafer substrate and a gate dielectric layer disposed over the substrate. A surface of the wafer substrate is hydrophilic and functionalized with linker molecules terminated with amine groups. A network of separated nanotubes is disposed over the functionalized surface of the substrate with the network of separated nanotubes including semiconducting nanotubes. Source and drain electrodes are formed on the wafer substrate. Also, source and drain metal contacts are formed on the wafer substrate. An organic light-emitting diode display device is connected to the display control circuit.

Implementations can optionally include one or more of the following features. The substrate of the separated semiconducting nanotube thin-film transistor device can include silicon, glass, or polyethylene terephthalate (PET). The gate dielectric layer of the separated semiconducting nanotube thin-film transistor device can include SiO₂, Al₂O₃, or HfO₂. The linker molecules terminated with amine groups in the separated semiconducting nanotube thin-film transistor device can include aminopropyltriethoxy silane (APTES).

In another aspect, a method of fabricating active matrix organic light-emitting diodes (AMOLED) can include fabricating a wafer-scale separated semiconducting nanotube network. Fabricating a wafer-scale separated semiconducting nanotube network can include providing a wafer substrate and a gate dielectric layer deposited over the substrate. Fabricating a wafer-scale separated semiconducting nanotube network can include cleaning a surface of the wafer substrate to cause the surface to become hydrophilic. Also, fabricating a wafer-scale separated semiconducting nanotube network can include functionalizing the cleaned surface of the wafer substrate by applying a solution comprising linker molecules terminated with amine groups. Fabricating a wafer-scale separated semiconducting nanotube network can include assembling a network of separated nanotubes over the functionalized surface by applying to the functionalized surface a separated nanotube solution that includes semiconducting nanotubes. Also, fabricating a wafer-scale separated semiconducting nanotube network can include removing residual materials from the assembled separated nanotubes. Fabricating active matrix organic light-emitting diodes (AMOLED) can include fabricating a transistor device using the wafer-scale separated semiconducting nanotube network, which includes forming source and drain electrodes on the wafer substrate having the wafer-scale separated semiconducting nanotube network. Fabricating a transistor device using the wafer-scale separated semiconducting nanotube network includes forming source and drain metal contacts on the wafer substrate having the wafer-scale separated semiconducting nanotube network, and removing unwanted separated nanotubes from the wafer substrate that are outside a channel region. Fabricating active matrix organic light-emitting diodes (AMOLED) can include integrating multiple transistor devices and OLEDs to form pixel arrays.

Implementations can optionally include one or more of the following features. The substrate of the separated semiconducting nanotube thin-film transistor device can include silicon, glass, or polyethylene terephthalate (PET). The gate dielectric layer of the separated semiconducting nanotube thin-film transistor device can include SiO₂, Al₂O₃, or HfO₂. The linker molecules terminated with amine groups in the separated semiconducting nanotube thin-film transistor device can include aminopropyltriethoxy silane (APTES). Fabricating the wafer-scale separated nanotube assembly can include providing an Indium-Tin-Oxide (ITO) layer as a back-gate for the transistor devices and an anode electrode for the OLEDs. Additionally, vias can be opened on top of the anode of the OLEDs, with the vias providing electrical paths between the ITO layer and metal interconnects. Depositing the gate dielectric layer can include depositing Al₂O₃ by atomic layer deposition (ALD). Also, a SiO₂ layer can be provided as a passivation layer for the OLEDs.

The methods as described herein can be used to implement an active matrix organic light-emitting diode (AMOLED) device, which includes pixel arrays. The pixel array includes separated semiconducting nanotube transistors; and OLEDs integrated with the separated semiconducting nanotube transistors. The separated semiconducting nanotube transistors can include a back-gate for the separated semiconducting nanotube transistors and an anode for the OLEDs. The separated semiconducting nanotube transistors can include a gate dielectric layer deposited by atomic layer deposition (ALD); and separated semiconducting nanotubes deposited onto the ALD deposited gate dielectric layer.

Implementations can optionally include one or more of the following features. The separated nanotubes can be deposited over a surface of a substrate functionalized with linker molecules terminated with amine groups. The linker molecules terminated with amine groups can include aminopropyltriethoxy silane (APTES). The back gate can include an Indium-Tin-Oxide (ITO) layer. Also, vias can be opened on top of the anode of the OLED to provide an electrical path between the back gate and metal interconnects. A passivation layer can be provide for OLED deposition.

In another aspect, a method of fabricating an N-type separated semiconducting nanotube transistor device can include providing a wafer substrate comprising a back-gate layer and a gate dielectric layer. A surface of the substrate is functionalized using linker molecules terminated with amine groups. A network of separated semiconducting nanotubes is assembled over the functionalized surface. Source and drain electrodes are formed on the separated semiconducting nanotube network. Also, source and drain metal contacts are formed by metal deposition followed by a lift-off process. Unwanted separated nanotubes outside a channel region are removed; and a passivation layer is deposited over the wafer substrate.

Implementations can optionally include one or more of the following features. The substrate can include silicon, glass, or polyethylene terephthalate (PET). The back-gate layer can include silicon, glass, or polyethylene terephthalate (PET). The gate dielectric layer can include SiO₂, Al₂O₃, or HfO₂. The linker molecules terminated with amine groups can include aminopropyltriethoxy silane (APTES). Removing the unwanted separated nanotubes can include using photo-lithography and O₂ plasma to remove the unwanted separated nanotubes outside the device channel region. Depositing the passivation layer can include depositing HfO₂ or Al₂O₃ passivation layer using atomic layer deposition (ALD). Also, source and drain probing pads can be opened by photo-lithography and wet etching.

The methods described herein can be used to implement an N-type separated semiconducting nanotube transistor device, which includes a wafer substrate with a back-gate layer and a gate dielectric layer. A surface of the substrate is functionalized using linker molecules terminated with amine groups. A network of separated semiconducting nanotubes is assembled over the functionalized surface. Source and drain electrodes are patterned on the separated semiconducting nanotube network. Also, source and drain metal contacts are formed on the substrate; and a passivation layer is deposited over the wafer substrate.

Implementations can optionally include one or more of the following features.

The substrate can include silicon, glass, or polyethylene terephthalate (PET). The back-gate layer can include silicon, glass, or polyethylene terephthalate (PET). The gate dielectric layer can include SiO₂, Al₂O₃, or HfO₂. The linker molecules terminated with amine groups can include aminopropyltriethoxy silane (APTES). The passivation layer can include a HfO₂ or Al₂O₃ passivation layer. Also, source and drain probing pads can be opened by photo-lithography and wet etching.

The subject matter described in this specification potentially can provide one or more of the following advantages. Separated nanotubes can be used to fabricate TFTs to avoid high-temperature processing and obtain high device mobility. Also, using separated nanotubes can help to avoid the existence of both metallic and semiconductive nanotubes in the TFTs to increase the average device on/off ratio to beyond 10⁴ without requiring additional fabrication steps of stripe patterning and large device dimensions.

### BRIEF DESCRIPTION OF THE DRAWINGS

FIG. 1 shows a schematic of aminopropyltriethoxy silane (APTES) assisted deposition.

FIG. 2 is a process flow diagram of a process for performing wafer scale-separated nanotube assembly or network.

FIG. 3 shows a length distribution of semiconductive nanotubes measured by field-emission scanning electron microscope (FE-SEM).

FIGS. 4 and 5 are SEM images of separated nanotubes deposited on Si/SiO₂ substrates with and without APTES functionalization, respectively.

FIG. 6 shows a photograph of a 3 inch Si/SiO₂ wafer after APTES assisted nanotube deposition.

FIG. 7 is a process flow diagram describing a device fabrication process that follows the nanotube deposition process.

FIG. 8 is a photograph of a wafer after electrode patterning.

FIG. 9 shows a schematic diagram of a back-gated SN-TFT built on separated nanotube thin-film with Ti/Pd (5 Å/70 nm) contacts and SiO₂ (50 nm) gate dielectric over a silicon substrate.

FIG. 10 shows an SEM image of a channel of a typical SN-TFT with 4 μm channel length.

FIGS. 11 and 12 show output (I_{D}-V_{D}) characteristics of a typical SN-TFT (L=20 μm, and W=100 μm) measured in triode region and saturation region, respectively.

FIG. 13 shows the transfer (I_{D}-V_{G}) characteristics and gₘ-V_{G} characteristics of the same representative device with V_{D}=1V.

FIG. 14 shows uniformity of devices by showing current density (Iₒₙ/W) measured at V_{D}=1V and threshold voltage (Vₜₕ) of 10 representative SN-TFTs with L=4 μm.

FIG. 15 shows average normalized on-current densities (Iₒₙ/W) of transistors (separated nanotubes and mixed nanotubes) with various channel lengths measured at V_{D}=1 V and V_{G}=−10 V, showing that the on-current density is approximately reversely proportional to the channel length.

FIG. 16 is a data chart of on-currents that shows that the average on-current of the TFTs with various channel lengths is approximately proportional to the channel width.

FIG. 17 shows differences in on/off ratios for TFTs fabricated with separated nanotubes and mixed nanotubes.

FIG. 18 shows normalized device transconductance (gₘ/W) and mobility of devices with various channel lengths.

FIG. 19 is a process flow diagram of a process for conducting a numerical simulation of nanotube TFTs with various channel lengths to extract their on/off ratios.

FIGS. 20a and 20b show representative networks for separated nanotubes and mixed nanotubes.

FIG. 21 shows results of simulation compared with measurement results.

FIG. 22a shows transfer characteristics of a typical SN-TFT device connected to and controlling an OLED device.

FIG. 22b shows a current flowing through an OLED (I_{OLED}) with a schematic of an OLED control circuit shown in the inset.

FIG. 22b illustrates that by controlling V_{DD} and V_{G} that worked as the input for the circuit, the current flow can be controlled through the OLED.

FIG. 22c shows relationships between the current and output light intensity versus applied voltage.

FIG. 22d shows I-V characteristics representing the current flowing through the OLED, which is successfully modulated by V_{G} by a factor of 1140.

FIG. 22e shows optical photographs that represent the OLED under various input voltages, with reference numbers 1, 2, 3, 4, 5, and 6 corresponding to the inputs of −10, −8, −6, −4, −2, and 0 V, respectively.

FIG. 23 shows a process for fabricating active matrix organic light-emitting diodes (AMOLED) using SN-TFTs.

FIGS. 24 and 25 represent a layout a seven-segment AMOLED design and a layout of a 4×6 pixel array design, respectively.

FIG. 26 is a photograph showing a transparent AMOLED circuit fabricated on glass.

FIG. 27 is a schematic of an expected output from seven-segment and 4×6 pixel array AMOLED circuit.

FIG. 28 illustrates an N-type SN-TFTs device structure.

FIG. 29 is a process flow diagram of a process for fabricating an N-type SN-TFTs device.

FIG. 30 is a process flow diagram of a device fabrication process.

FIG. 31 is a photograph of an array of devices after fabrication.

FIG. 32 is an image from a field-emission scanning electron microscope (FE-SEM) showing a channel of a typical SN-TFT with 5 μm channel length.

FIG. 33 shows the electrical performance of SN-TFTs.

FIG. 34a is a diagram showing a mechanism of an N-type SN-TFT by ALD high-K oxide layer with a band structure of a nanotube-metal contact with (solid line) and without (dash line) ALD layer at different gate voltages (V_{G}>0 V, V_{G}=0 V and V_{G}<0 V).

FIG. 34b shows the transfer characteristics of two devices before and after ALD.

FIGS. 34c and 34d show the transfer characteristics for ALD of HfO₂ and Al₂O₃ respectively.

FIG. 35a shows a drain current-gate voltage relationship.

FIG. 35b shows average ratios of Iₒₙ_{_{—}}_{N}/Iₒₙ_{_{—}}_{P} after ALD of HfO₂ and ALD of Al₂O₃.

FIG. 36a exhibits the normalized on-current densities (Iₒₙ/W) of the transistors with various channel lengths and channel width measured at V_{D}=1 V, V_{G}=5 V for N-type SN-TFTs and −5 V for P-type SN-TFTs.

FIG. 36b shows a relationship between average on-current and channel width.

FIG. 36c shows the on/off ratios of the N-type and P-type SN-TFTs.

FIG. 36d shows the devices mobility of the SN-TFTs.

FIGS. 37a and 37b show transfer (I_{D}-V_{G} curves 3700) and output (I_{D}-V_{D} curves 3710) characteristics of two typical P-type and N-type SN-TFTs selected to have the same channel geometry (L=5 μm, W=200 μm).

FIG. 37c shows inverter voltage and current transfer characteristics with the inset showing two transistors connected into a CMOS inverter by a probe station.

FIG. 37d shows the gain of the inverter.

Like reference symbols and designations in the various drawings indicate like elements.

### DETAILED DESCRIPTION

Pre-separated, semiconductive enriched carbon nanotubes can be used for thin-film transistors and display applications due to their high mobility, high percentage of semiconductive nanotubes, and room-temperature processing compatibility. Techniques, apparatus, materials and systems are described for implementing wafer-scale processing of separated nanotube thin-film transistors (SN-TFTs) for display applications, including key technology components such as wafer-scale assembly or network of high-density, uniform separated nanotube networks, high-yield fabrication of devices with superior performance, and demonstration of organic light-emitting diode (OLED) switching controlled by a SN-TFT. Based on separated nanotubes with 95% semiconductive nanotubes, solution-based assembly or network of separated nanotube thin films can be implemented on complete 3 inch Si/SiO₂ wafers, and wafer-scale fabrication can be performed to produce transistors with high yield (>98%), small sheet resistance (˜25 kΩ/sq), high current density (˜10 μA/μm), and superior mobility (˜52 cm²V⁻¹s⁻¹). Moreover, on/off ratios of >10⁴ can be achieved in devices with channel length L>20 μm. In addition, OLED control circuit can be implemented with the SN-TFT, and the modulation in the output light intensity can exceed 10⁴. The described techniques can be easily scaled to large areas and could serve as critical foundation for future nanotube-based display electronics and integrated circuits. The techniques can also be used for nanotube based transparent and flexible electronics.

The described techniques for implementing wafer-scale processing of SN-TFTs have potential application in display electronics. The techniques can be used to produce TFTs using only 95% enriched semiconductive nanotubes with overall better performance than previous work using 99% enriched nanotubes. The described techniques, systems, apparatus and materials can include the following components: (1) Uniform and high density separated nanotube thin-films can be deposited onto 3 inch Si/SiO₂ wafers using a facile solution based assembly or network method; (2) Wafer-scale device fabrication can be performed on 3 inch Si/SiO₂ wafers to yield SN-TFTs with high yield (>98%), small sheet resistance (˜25 kΩ/sq), high current density (˜10 μA/μm), high mobility (˜52 cm²V⁻¹s⁻¹) and good on/off ratio (>10⁴); and (3) OLED control circuit can be implemented using the SN-TFT with output light intensity modulation over 10⁴. The described wafer-scale processing of SN-TFTs shows significant advantage over conventional platforms with respect to scalability, reproducibility and device performance, and suggests a practical and realistic approach for nanotube based integrated circuit applications.

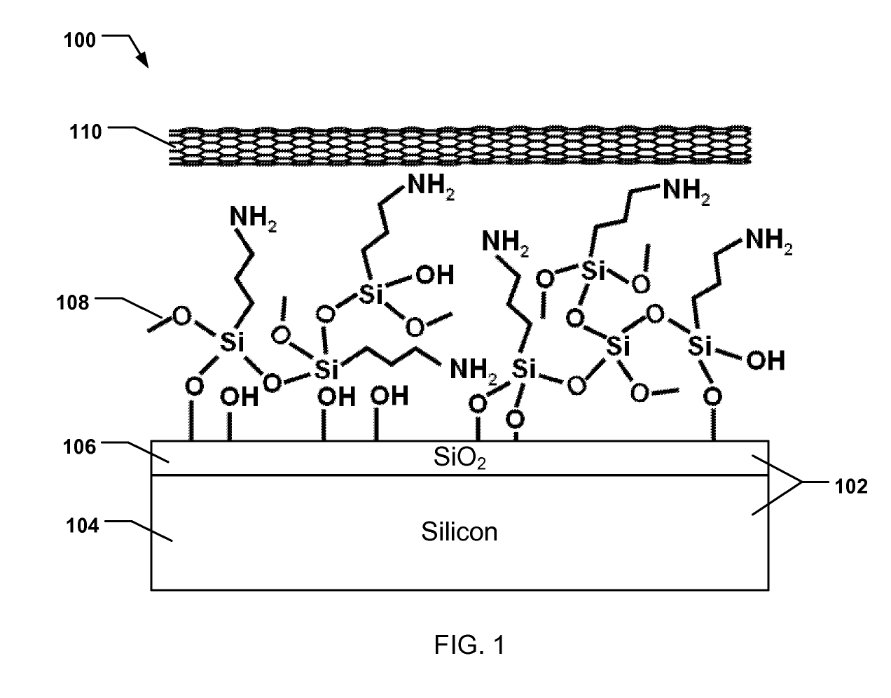

FIGS. 1-8 illustrate an exemplary wafer-scale processing of SN-TFTs including aminosilane assisted nanotube deposition and device fabrication. In order to improve the density and uniformity of the solution based nanotube assembly or network, aminosilane can be introduced due to its well-known affinity to the carbon nanotubes. For example, aminopropyltriethoxy silane (APTES) can be used to functionalize the Si/SiO₂ surface to form amine-terminated monolayer. FIG. 1 shows a schematic 100 of APTES assisted deposition. The schematic includes a wafer (e.g., Si/SiO₂) 102 made up of a silicon layer 104 and a dielectric layer 106 disposed over the silicon layer 104. The substrate can include other materials such as glass, or polyethylene terephthalate (PET). The dielectric layer can include any dielectric materials such as SiO₂, Al₂O₃, or HfO₂. Linking molecules terminated with amine groups 108, such as, such as APTES or 3-Aminopropylphosphonic acid can be used to functionalize the Si/SiO₂ surface, and separated carbon nanotubes 110 are assembled over the APTES layer 108.

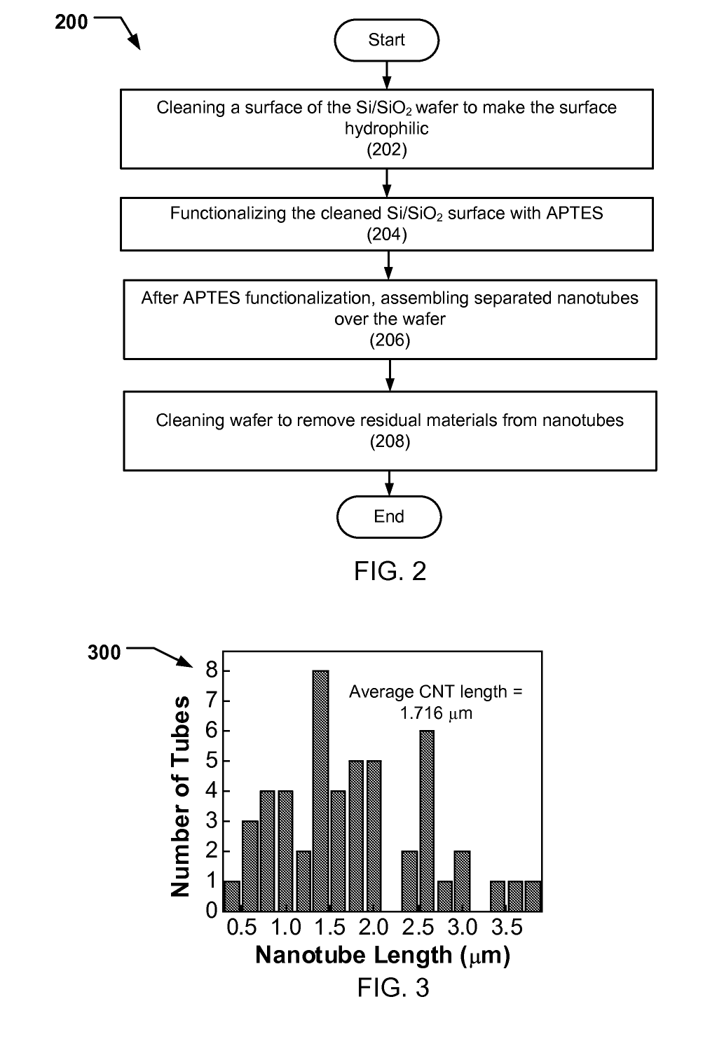

FIG. 2 is a process flow diagram of a process 200 for performing wafer scale-separated nanotube assembly or network. The surface of the Si/SiO₂ wafer is cleaned to make the surface hydrophilic (202). For example, corona discharge generator can be used to generate UV ozone to clean the surface of the Si/SiO₂ wafer making it hydrophilic. The cleaned Si/SiO₂ surface is functionalized with APTES (204). For example, the cleaned wafer can be immersed into diluted APTES solution (e.g., 3 drops of APTES in 20 mL of isopropanol alcohol (IPA)) for 10 minutes, then rinsed with IPA and blew dry thoroughly. After APTES functionalization, separated nanotubes are assembled over the wafer (206). For example, the wafer can be immersed into the commercially available (NanoIntegris, Inc.) 0.01 mg/mL separated nanotube solution with 95% semiconducting nanotubes for 20 minutes. The enrichment of semiconducting nanotubes in the separated nanotube solution can be confirmed by UV-Vis-NIR absorption spectroscopy. The wafer with the separated nanotubes assembled is cleaned to remove any residual materials from the nanotubes. For example, IPA and deionized water rinsing can be used to remove the sodium dodecyl sulfate (SDS) residuals on the nanotubes, and the wafer can be blown dry with N₂.

FIG. 3 shows a length distribution 300 of the above assembled semiconductive nanotubes measured by field-emission scanning electron microscope (FE-SEM). The average length is measured to be 1.7 μm, which is longer than 1 μm for 99% semiconducting nanotubes as reported in the literature.

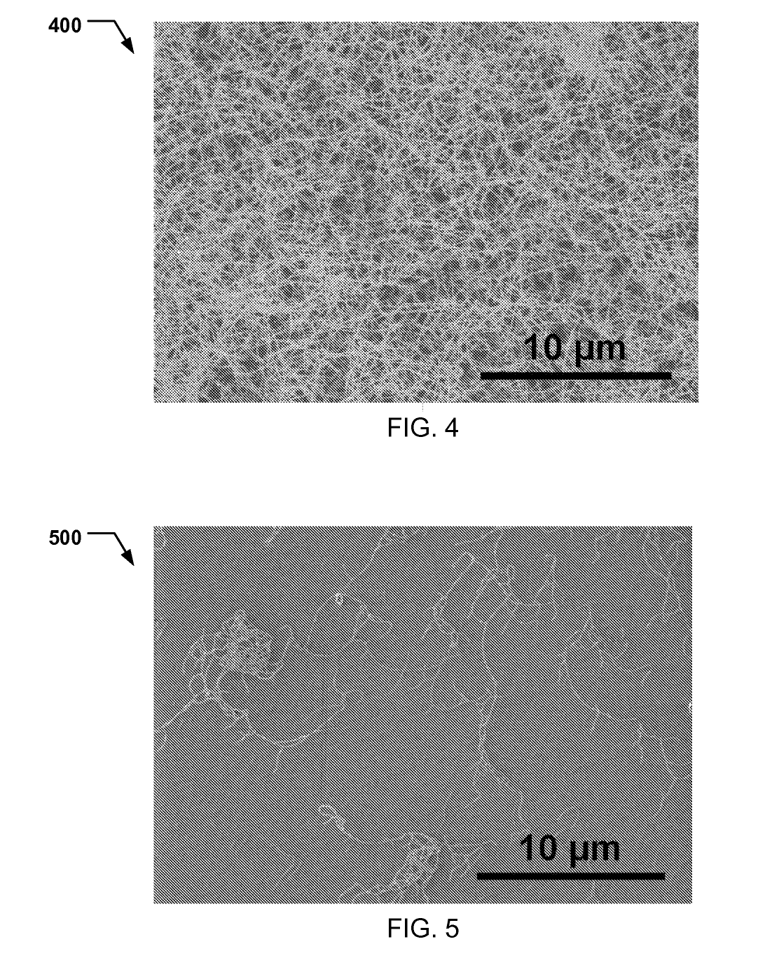

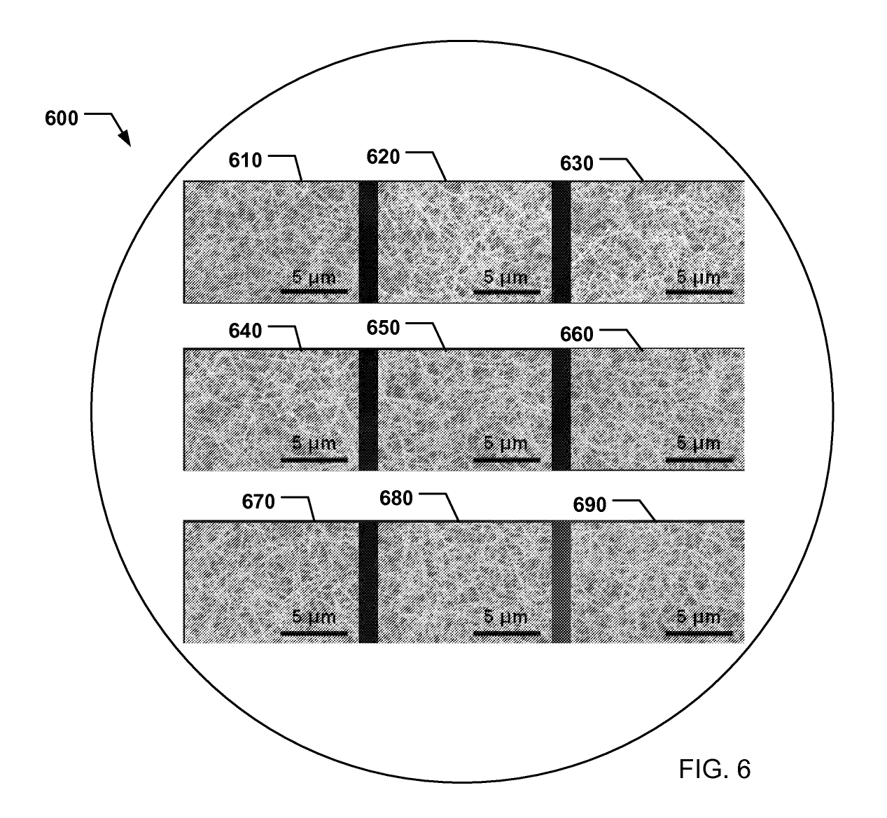

FE-SEM can be used to inspect the surface after nanotube assembly or network. FIGS. 4 and 5 are the SEM images 400 and 500 of the separated nanotubes deposited on Si/SiO₂ substrates with and without APTES functionalization, respectively. The images 400 and 500 show that a sample with APTES functionalization (see image 400) provides much higher nanotube density (24˜32 tubes/μm²) than a sample without APTES (<0.5 tubes/μm²) (see image 500). Besides high density, APTES functionalization can also help to give uniform deposition through out the wafer. FIG. 6 shows a photograph 600 of a 3 inch Si/SiO₂ wafer after APTES assisted nanotube deposition. There is no abnormal color or residual material left on the wafer after the deposition and cleaning process. In order to determine the deposition uniformity, SEM images can be taken at nine different locations on the wafer. In FIG. 6, the nine locations of the SEM images 910, 920, 930, 940, 950, 960, 970, 980 and 990 on the wafer correspond to the approximate locations on the wafer where the images were taken and all the scale bars correspond to 5 μm. The SEM images 910, 920, 930, 940, 950, 960, 970, 980 and 990 indicate that high density, uniform deposition is achieved throughout the 3 inch wafer.

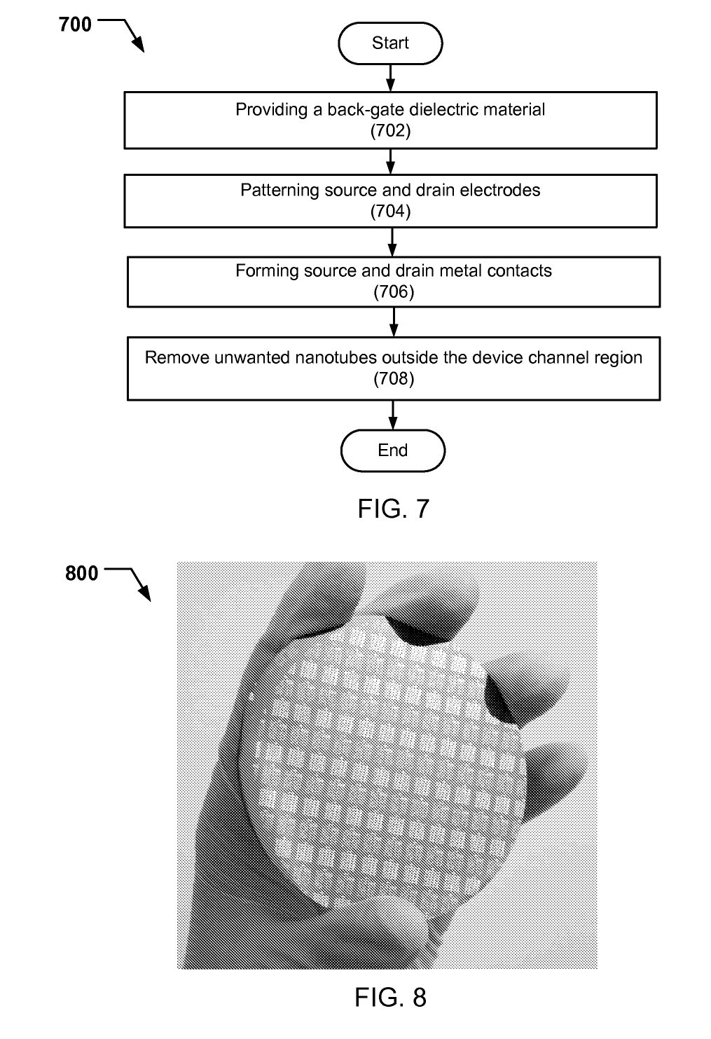

FIG. 7 is a process flow diagram describing a device fabrication process 700 that follows the nanotube deposition process. A back-gate dielectric material is provided (702). The back-gate dielectric material can include SiO₂, Al₂O₃, or HfO₂. For example, 50 nm SiO₂ can be used to act as the back-gate dielectric. The source and drain electrodes are patterned, for example, by photo-lithography (704), and source and drain metal contacts are formed, for example, by depositing 5 Å Ti and 70 nm Pd followed by a lift-off process (706). Because the separated nanotube thin film covers the entire wafer, in order to achieve accurate channel length and width, and to remove the possible leakage in the devices, unwanted nanotubes outside the device channel region are removed (708). For example, photo-lithography and O₂ plasma can be used to remove the unwanted nanotubes outside the device channel region. FIG. 8 is a photograph 800 of a wafer after electrode patterning. The wafer includes SN-TFTs as described herein and other types of electronic devices. Such SN-TFTs can be made with channel width (W) of 10, 20, 50, 100, and 200 μm, and channel length (L) of 4, 10, 20, 50, and 100 μm.

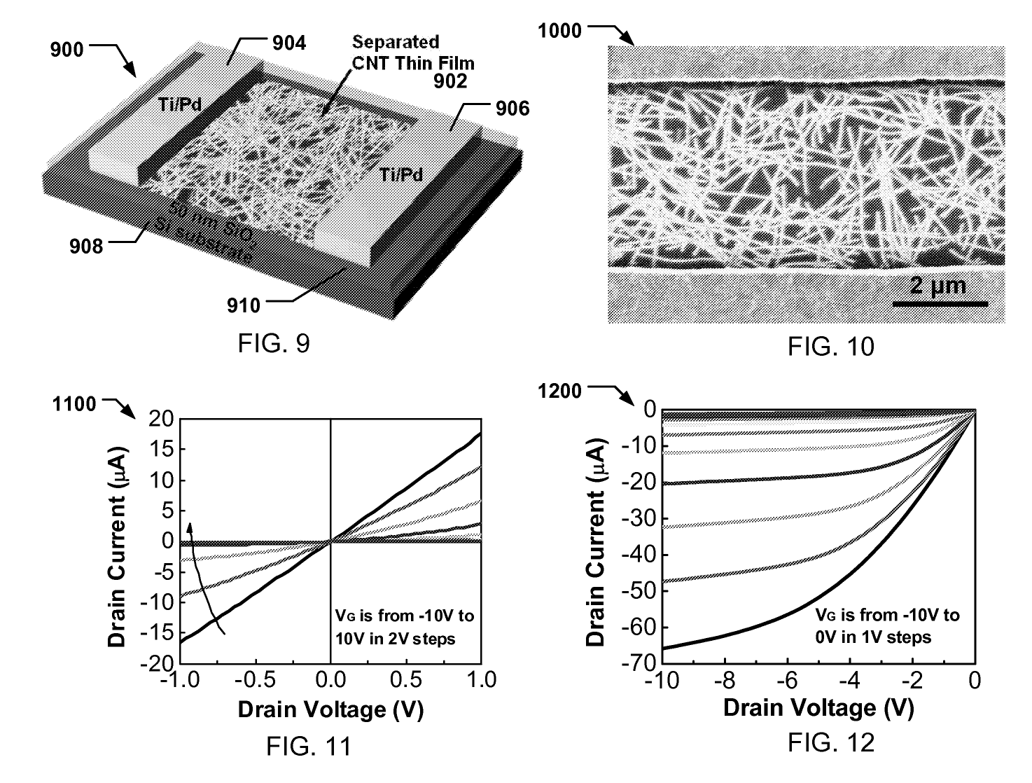

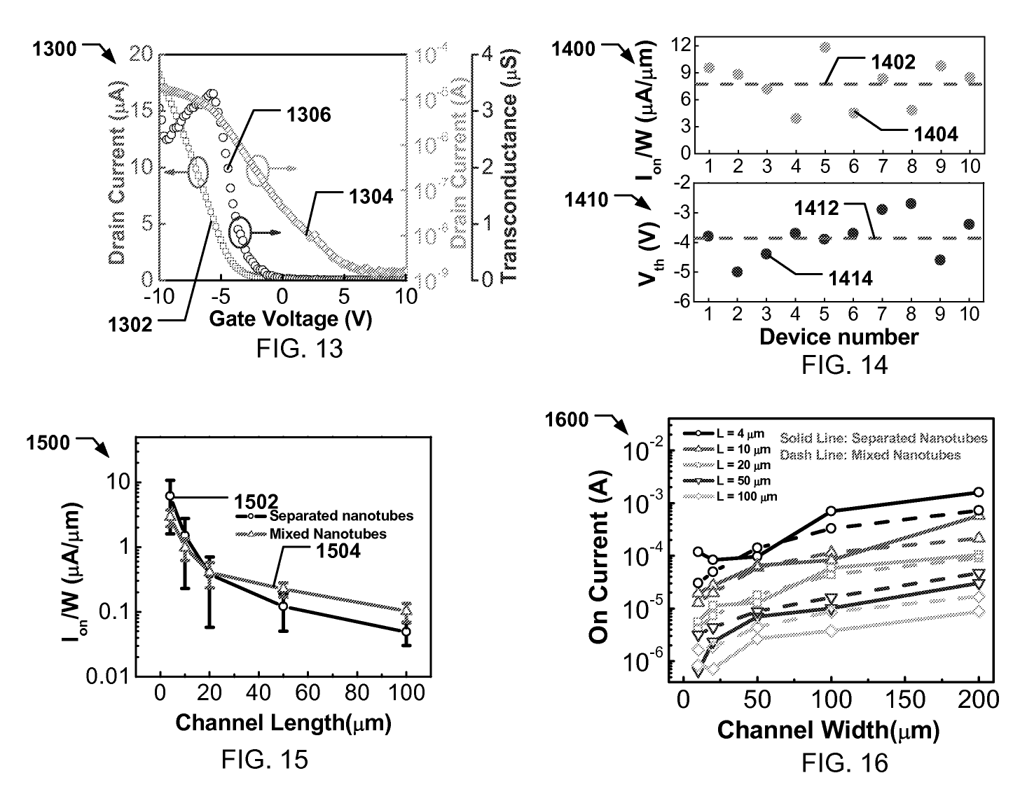

The following describes the electrical performance of the SN-TFTs as basic components for macroelectronic integrated circuits and display electronics. FIG. 9 shows a schematic diagram 900 of a back-gated SN-TFT built on separated nanotube thin-film 902 with Ti/Pd (5 Å/70 nm) contacts 904 and 906 and SiO₂ (50 nm) gate dielectric 908 over a silicon substrate 910. The SEM image 100 of the channel of a typical SN-TFT with 4 μm channel length is shown in FIG. 10. FIGS. 11, 12 are the output (I_{D}-V_{D}) characteristics 1100 and 1200 of a typical SN-TFT (L=20 μm, and W=100 μm) measured in triode region and saturation region, respectively. The I_{D}-V_{D} curves appear to be very linear for V_{D} between −1V and 1V, indicating that ohmic contacts are formed between the electrodes and the nanotubes. Under more negative V_{D}, these devices typically exhibit saturation behavior, as shown in FIG. 12. FIG. 13 shows the transfer (I_{D}-V_{G}) characteristics (red: linear scale 1302, green: log scale 1304) and gₘ-V_{G} characteristics (blue: 1306) of the same representative device with V_{D}=1V. The on-current at V_{D}=1V is measured to be 18.5 μA, corresponding to a current density of 0.185 μA/μm. The on/off ratio exceeds 10⁴ and the transconductance is 3.3 μS. Furthermore, due to the high density and uniform nature of the separated nanotube thin-film deposited on Si/SiO₂ substrates with APTES functionalization, the SN-TFTs are also expected to behave uniformly. The uniformity of the devices is illustrated in FIG. 14 which shows the current density (Iₒₙ/W) 1400 measured at V_{D}=1V and threshold voltage (Vₜₕ) 1410 of 10 representative SN-TFTs with L=4 μm. The red lines 1402 and 1412 represent the average values. Those device parameters have much smaller distribution compared with single nanotube devices.

CVD grown nanotube thin-films with mixed nanotubes can be used to fabricate TFTs for applications in flexible devices and integrated circuits. However, CVD grown nanotube networks can include co-existence of metallic and semiconductive nanotubes, with approximate 33% nanotubes being metallic. Stripe-patterning of CVD nanotube network could be used to remove heterogeneous percolative transport through metallic nanotube networks and increase the average device on/off ratio to 10⁴. Stripe-patterning of CVD nanotube network involves additional fabrication steps and results in large device dimensions.

The performance of SN-TFTs based on separated nanotubes (5% metallic) as described herein is compared with TFTs based on CVD grown mixed nanotubes (33% metallic). The CVD recipe can be fine tuned to produce TFTs with a current drive (Iₒₙ/W) similar to SN-TFTs. FIGS. 15-17 summarize the results of the comparison after the measurement of 200 nanotube TFTs with various channel lengths and channel widths. Half of these devices are based on separated nanotubes and the other half based on mixed nanotubes. The device yield is more than 98%, and the few un-conductive devices are due to the peel-off of metal contact during fabrication process.

FIG. 15 exhibits the average normalized on-current densities (Iₒₙ/W) 1500 of the transistors (separated nanotubes 1502 and mixed nanotubes 1504) with various channel lengths measured at V_{D}=1 V and V_{G}=−10 V, showing that the on-current density is approximately reversely proportional to the channel length. The highest on-current density is measured to be 10 μA/μm and is achieved in devices with L=4 μm. This value is comparable to the devices based on parallel aligned nanotubes with a typical nanotube density of 5 tubes/μm. FIG. 16 is a data chart of on-currents 1600 that shows that the average on-current of the TFTs with various channel lengths is approximately proportional to the channel width. The highest average on-current 1.59 mA is achieved in devices with L=4 μm and W=200 μm. Based on the information in FIG. 16, we can further extract the best sheet resistance of the separated nanotube thin-film to be ˜25 kΩ/sq, which is 8 times better than 200 kΩ/sq reported in the previous publication.

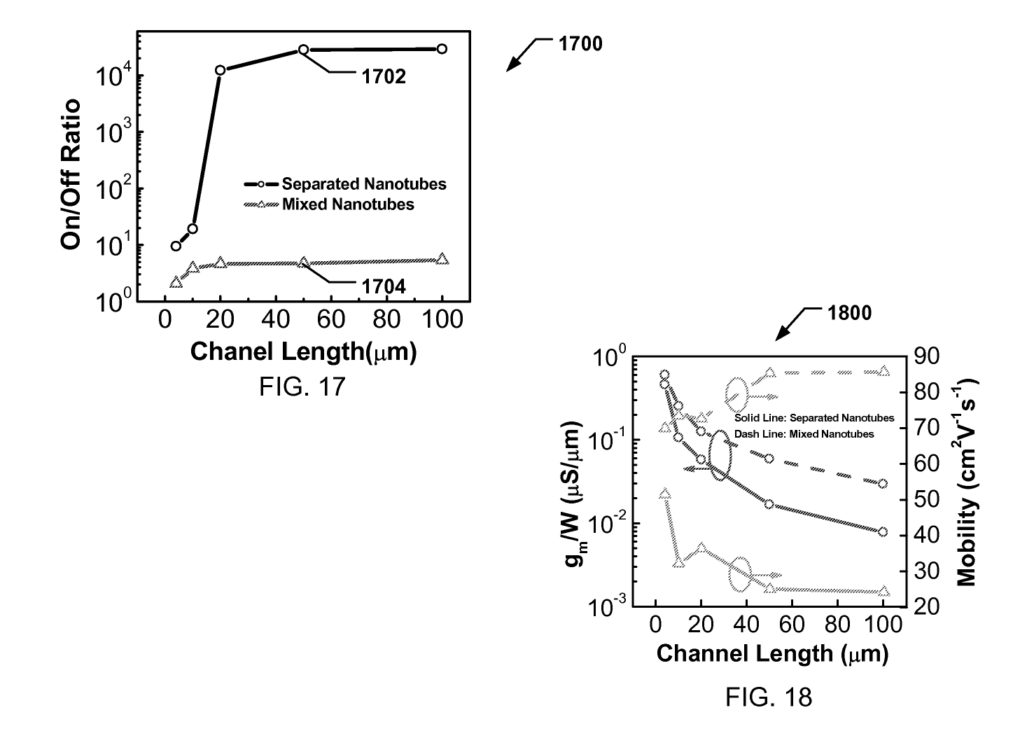

For TFTs fabricated with separated nanotubes and mixed nanotubes, the major difference is expected to be the on/off ratio, and the difference is explained in the data chart 1700 of FIG. 17. The on/off ratio vs. channel length for the separated nanotubes is shown in open circles 1702. The on/off ratio vs. channel length for the mixed nanotubes is shown in open triangles 1704. First of all, as the channel length increases, the average on/off ratio of both SN-TFTs and Mixed nanotubes TFTs increases. This can be explained by the decrease in the probability of percolative transport through metallic nanotube networks as the device channel length increases. On the other hand, SN-TFTs have much higher on/off ratio compared with mixed nanotube TFTs due to the small percentage of metallic nanotubes. For the mixed nanotube TFT, with 33% metallic nanotubes, the on/off ratio stays in the range of 2 to 10 as the channel length increases from 4 μm to 100 μm. In contrast, for SN-TFT, with only 5% metallic nanotubes, the on/off ratio improves significantly from 10 to above 10⁴ as the channel length increases from 4 μm to 100 μm. The turning point happens between 10 μm and 20 μm. When L>20 μm, more than 90% of the devices exhibit on/off ratio higher than 10³. This amount of on/off ratio is large enough for most kinds of integrated circuit applications. Similar results have also been reported in previous work done by the IBM research group. For their work, the turning point happens between 2 μm and 4 μm. The reason that their turning point happens at smaller channel length is that they used 99% semiconductive nanotubes. By using higher purity semiconductive enriched nanotubes, on one hand, it can help to achieve sufficient on/off ratio with smaller channel length, thus smaller device area; on the other hand, since higher purity requires more ultracentrifugation which will give rise to shorter nanotube length, it can cause more nanotube percolation and hurt the mobility of the devices as discussed below.

Besides the on current density and on/off ratio, there are two more important figures of merit for SN-TFTs, which are device transconductance (gₘ) and mobility (μ_{device}). The normalized device transconductance (gₘ/W) and mobility of devices with various channel lengths are characterized and are plotted in the data chart 1800 of FIG. 18. Solid lines represent separated nanotubes and dashed lines represent mixed nanotubes. gₘ is extracted from the maximum slope of the transfer characteristics measured at V_{D}=1 V, and is normalized to device channel width. From the figure, one can find that as channel length increases, gₘ/W decreases, this is because gₘ/W is also inversely proportional to channel length.

Based on the normalized transconductance, the mobility of the nanotube thin-film can be further extracted. The SN-TFTs exhibit hysteresis. For consistency, gₘ derived from the forward sweep for all the mobility calculations can be used. Under V_{D}=1 V, devices operate in triode region, so the device mobility can be calculated from the following equation,

$${μ}_{device} = \frac{L}{{V}_{D} {C}_{ox} W} \cdot \frac{d {I}_{d}}{d {V}_{g}} = \frac{L}{{V}_{D} {C}_{ox}} \cdot \frac{{g}_{m}}{W} ,$$

where L and W are the device channel length and width, V_{D}=1 V, and Cₒₓ is the gate capacitance per unit area. The capacitance is calculated by considering the electrostatic coupling between nanotubes. For the device mobility of the SN-TFTs, the device mobility decreases as channel length increases, while for the mixed nanotube TFTs, the device mobility increases as channel length increases. The highest mobility of SN-TFTs is 52 cm²V⁻¹s⁻¹ and is achieved in devices with L=4 μm, while the highest mobility of mixed nanotube TFTs is 86 cm²V⁻¹s⁻¹ and is achieved in devices with L=100 μm. The reason for the difference can be related to nanotube length. For the separated nanotubes, the average length is small and is measured to be 1.7 μm, so the device mobility is limited by the percolative transport through nanotube network. As the device channel length increases from a value comparable to the nanotube length to a much larger value, there are significantly more tube-to-tube junctions introduced into the conduction path, causing the device mobility to decrease. In contrast, for the mixed nanotubes, the average length is much larger (>20 μm), so the device mobility is likely to be limited by the metal/nanotube contacts, similar to the case for aligned nanotube transistors. As the channel length increases, the effect of metal/nanotube contacts become less significant and the mobility increases. Our SN-TFTs exhibit mobility up to 52 cm²V⁻¹s⁻¹ which is more than five times higher than the previously reported work (10 cm²V⁻¹s⁻¹). The described improvement in the device performance can be attributed to longer nanotube length as described before. For instance, the average nanotube length in the described SN-TFTs is approximately 1.7 μm, while the nanotube length is about 1 μm for previous work. For transistors of similar channel length, using longer nanotubes would lead to less nanotube-nanotube junctions, and consequently higher mobility.

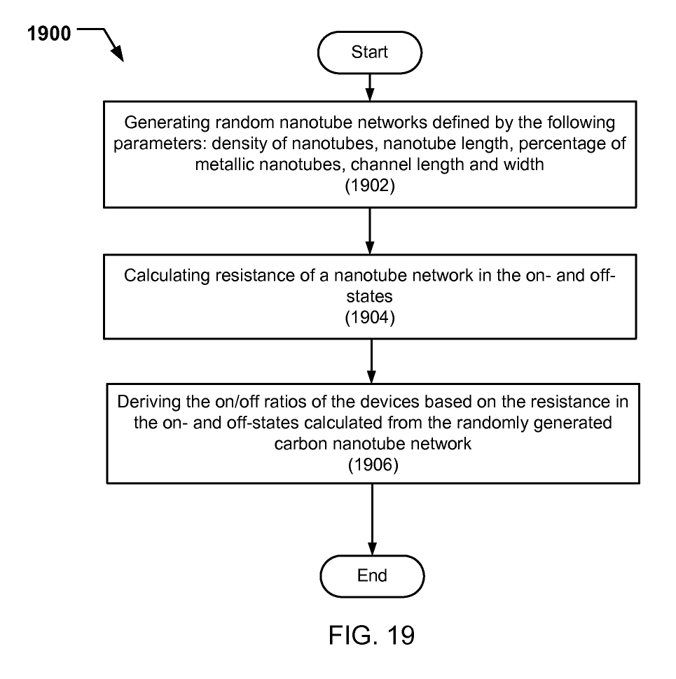

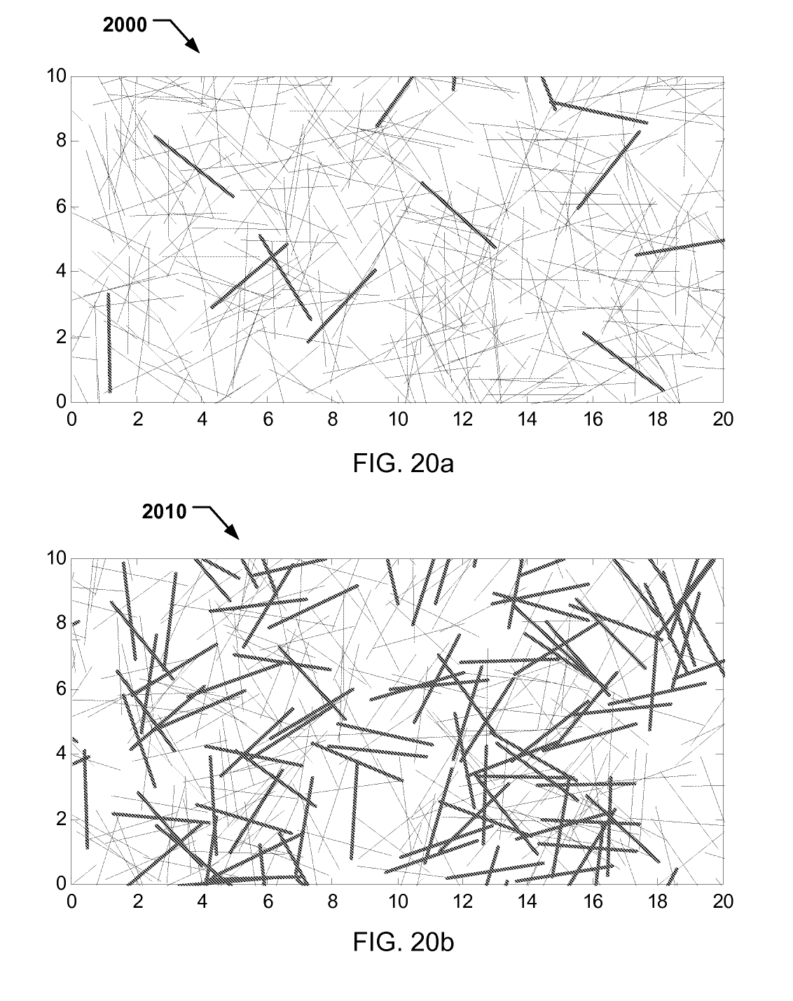

FIG. 19 is a process flow diagram of a process 1900 for conducting a numerical simulation of nanotube TFTs with various channel lengths to extract their on/off ratios. The numerical simulation can be performed to further assess the effect of the carbon nanotube percolation network on the performance of nanotube TFTs. The simulation can include the following. First, random nanotube networks can be generated to be defined by the following parameters: density of nanotubes, nanotube length, percentage of metallic nanotubes, channel length and width (1902). The representative networks 2000 and 2010 for separated nanotubes and mixed nanotubes are shown in FIGS. 20a and 20b respectively. Referring back to FIG. 19, the resistance of a nanotube network in the on- and off-states can be calculated (1904), where the resistance per unit length of a semiconducting nanotube in the on-state is assumed to be equal to the resistance per unit length of a metallic nanotube, and 10⁴ times larger in the off-state. Also, the fixed contact resistances between metallic/metallic, metallic/semiconductive, semiconductive/semiconductive nanotubes, and nanotubes/metal contacts can be assumed. Based on the resistance in the on- and off-states calculated from the randomly generated carbon nanotube network, the on/off ratios of the devices can be derived (1906).

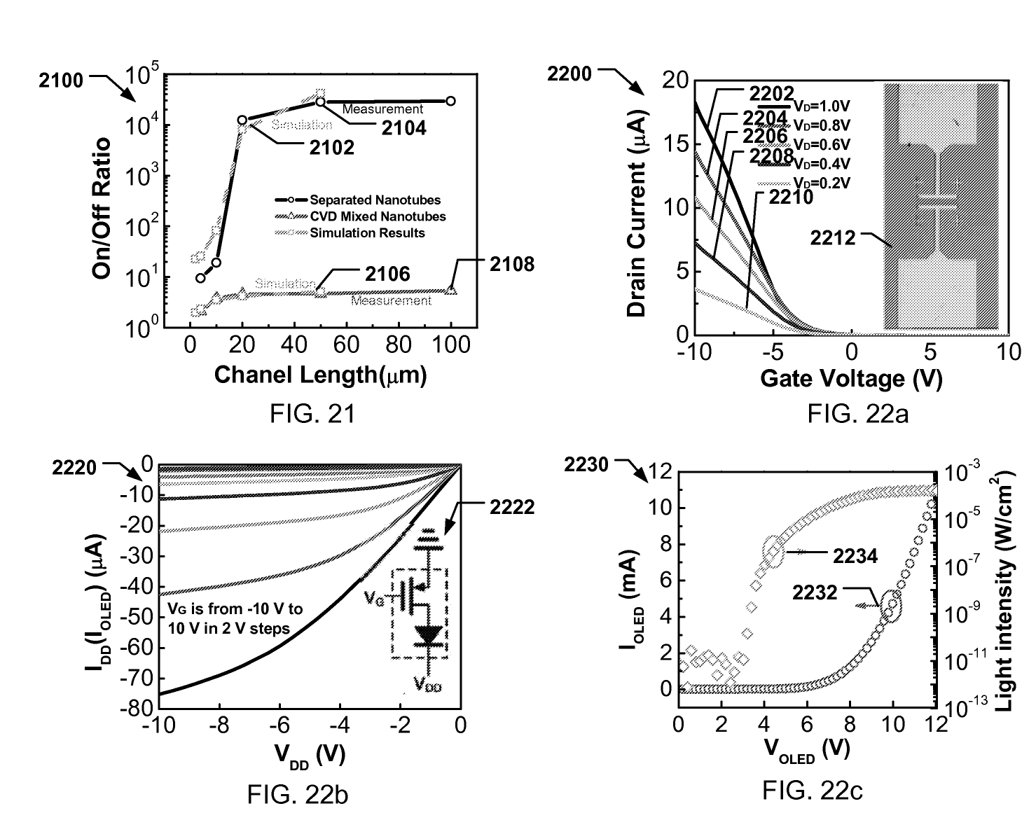

The simulation results are compared with the measurement results and are plotted in the data chart 2100 of FIG. 21. Based on this figure, the simulation results fit the measurement results well, which indicate that the nanotube percolation indeed plays a critical role in determining the on/off ratios of nanotube TFTs. The simulation results for the separated nanotubes represented by the data plot line 2102 are compared with the measurement results for the separated nanotubes represented by the data plot line 2104. The simulation results for the CVD mixed nanotubes represented by the data plot line 2106 are compared with the measurement results for the CVD mixed nanotubes represented by the data plot line 2108.

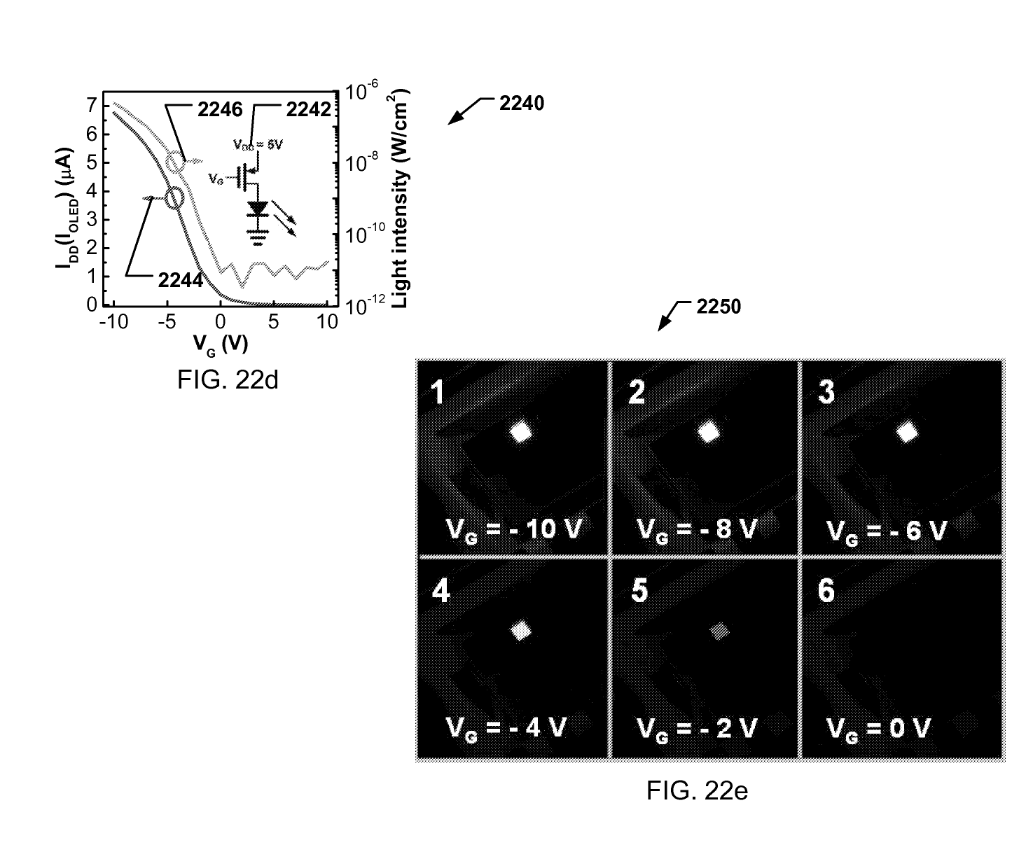

The high performance, uniform, high on/off ratio SN-TFTs fabricated as described herein can have various applications in display electronics. For example, an OLED can be connected to and controlled by a typical SN-TFT device whose transfer characteristics are shown in FIG. 22a. The transfer (I_{D}-V_{G}) characteristics for V_{D}=1.0 V (2202), 0.8 V (2204), 0.6 V (2206), 0.4 V (2208) and 0.2 V (2208) are shown for the device used to control the OLED (L=20 μm and W=100 μm). An example of an OLED includes a standard NPD/Alq3 OLED with multilayered configuration given as: ITO/4-4′-bis[N-(1-naphthyl)-N-phenyl-amino]biphenyl (NPD) [40 nm]/Tris(8-hydroxyquinoline)aluminum (Alq3) [40 nm]/LiF [1 nm]/Aluminum (Al) [100 nm]. The channel length of the SN-TFT is selected to be 20 μm so that the on/off reaches 10⁴ and can meet the requirement for controlling the OLED to switch on and off. The inset 2212 shows an optical microscope image of the device.

The schematic of the OLED control circuit is shown in the inset 2222 of FIG. 22b, where one SN-TFT is connected to an external OLED, and V_{DD} (<0 V) is applied to the cathode of the OLED. The OLED control circuit is characterized by sweeping the V_{DD} and Input voltage V_{G} and measure the current flow through the OLED (I_{OLED}). The plots of I_{OLED} 2220 shown in FIG. 22b shows field effect transistor like behavior, with various curves correspond to various values of input voltage (e.g., −10 V to 10 V in 2 V increments). FIG. 22b illustrates that by controlling V_{DD} and V_{G} that worked as the input for the circuit, the current flow can be controlled through the OLED. To fully understand the behavior of the OLED, it is further characterized and the current and output light intensity versus applied voltage behaviours 2230 are plotted in FIG. 22c. From the figure, we can see that the OLED gives nice diode I-V characteristic and in terms of the light intensity, the turn on voltage is about 3 V. The I-V curves shown in FIG. 22C represent the current through the OLED (I_{OLED}) 2232 and OLED light intensity 2234 versus the voltage applied across the OLED (V_{OLED}).

The data in FIGS. 22b and 22c confirms the switching of the OLED by applying V_{DD}=5 V to the source of the transistor and sweeping the input voltage V_{G} from −10 V to 10 V. FIG. 22d shows I-V characteristics 2240 representing the current (red curve) 2244 flowing through the OLED, which is successfully modulated by V_{G} by a factor of 1140. This current modulation leads to the control of the OLED light intensity as shown in the green curve 2246. When V_{G}=−10V, the OLED is on, and based on the measured light intensity, the brightness is calculated to be 16.5 Cd/m². When V_{G}=10V, the OLED is off and the brightness is calculated to be <0.001 Cd/m². The inset shows a circuit diagram 2242 of an OLED driven by a SN-TFT. The modulation in the OLED brightness is greater than 10⁴ and the significant change in the light intensity can be visually seen as shown in the optical photographs 2500 of FIG. 22e. The optical photographs 2500 represent the OLED under various input voltages, with reference numbers 1, 2, 3, 4, 5, and 6 correspond to the inputs of −10, −8, −6, −4, −2, and 0 V, respectively.

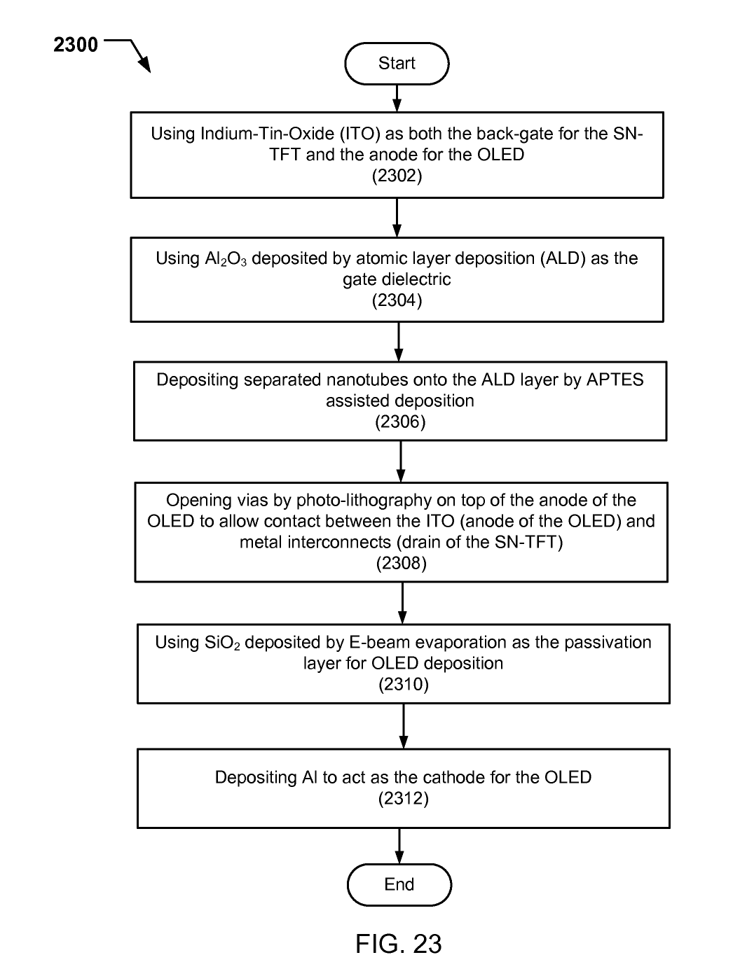

Furthermore, it is also possible to fabricate active matrix organic light-emitting diodes (AMOLED) using SN-TFTs as shown in the process flow diagram of FIG. 23. This can be done by integrating multiple SN-TFTs and OLEDs to form pixel arrays. In the AMOLED design, Indium-Tin-Oxide (ITO) can serve as both the back-gate for the SN-TFT and the anode for the OLED (2302), and Al₂O₃ deposited by atomic layer deposition (ALD) can be used as the gate dielectric (2304). Separated nanotubes can be deposited onto the ALD layer by APTES assisted deposition (2306). Vias can be opened by photo-lithography on top of the anode of the OLED to allow contact between the ITO (anode of the OLED) and metal interconnects (drain of the SN-TFT) (2308). Also, SiO₂ deposited by E-beam evaporation can be used as the passivation layer for OLED deposition. Vias can be opened by photo-lithography on top of the anode of the OLED and 40 nm of 4-4′-bis[N-(1-naphthyl)-N-phenyl-amino]biphenyl (NPD), 40 nm of Tris(8-hydroxyquinoline) aluminum (Alq3) and 1 nm of LiF can be deposited by thermal evaporation to form the OLED. This can be done in a glove both to prevent the sample from moisture. Additionally, Al can be deposited to act as the cathode for the OLED (2312).

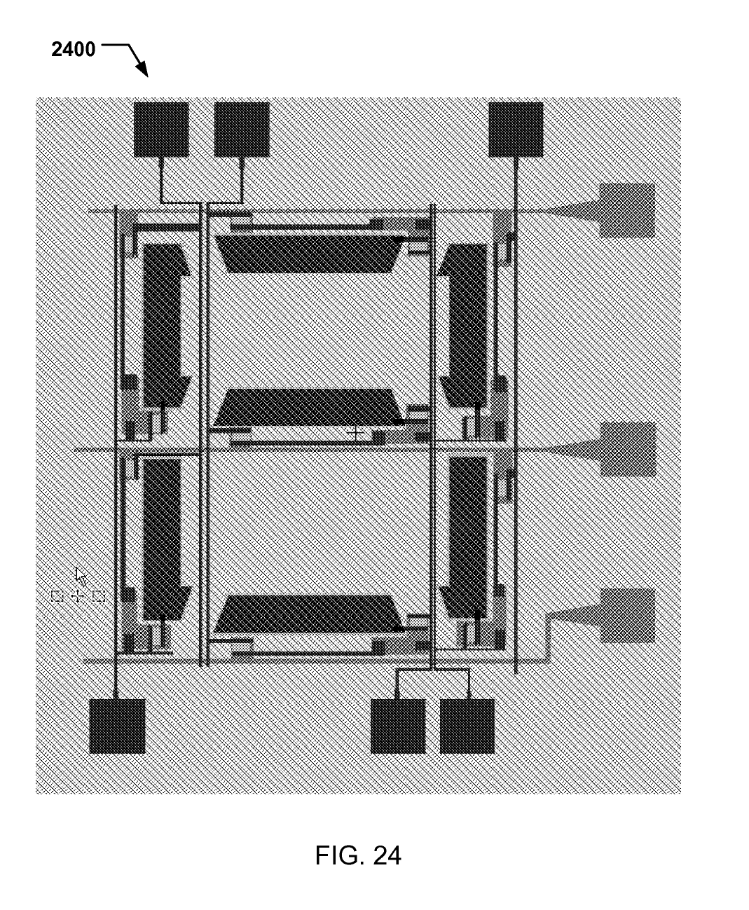

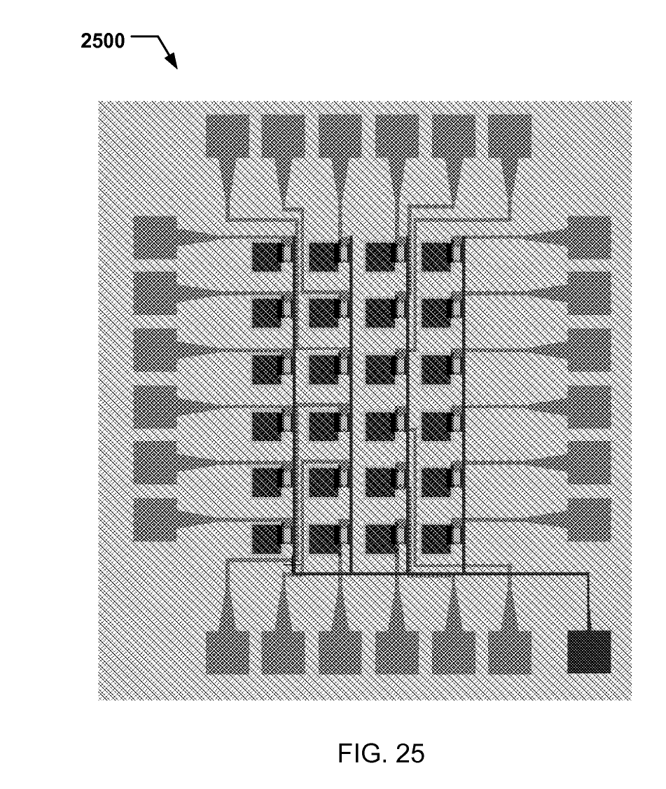

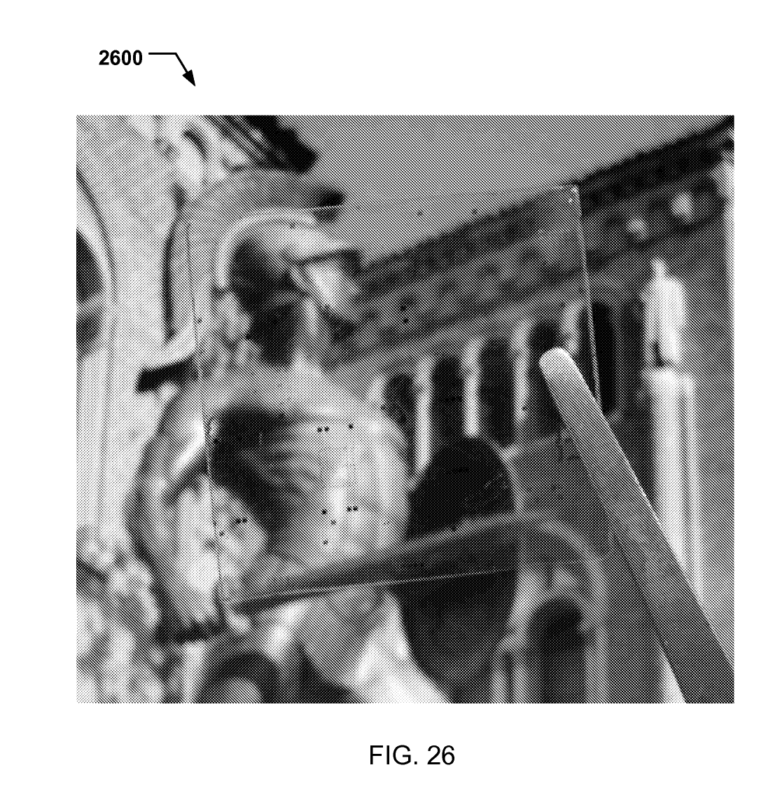

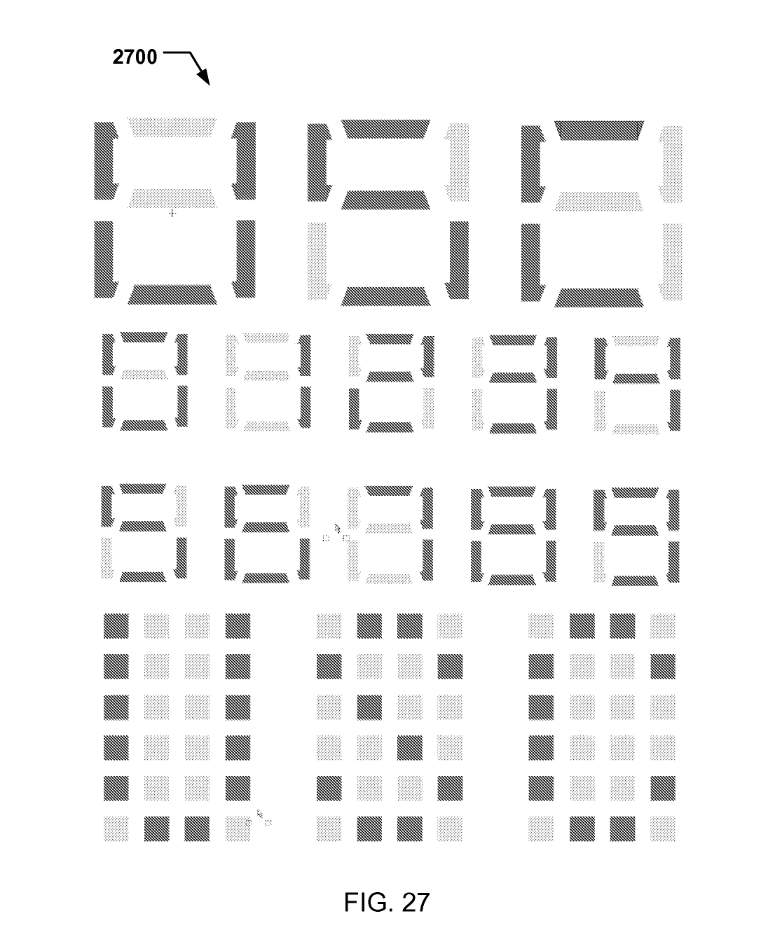

Details about the AMOLED fabrication are shown in FIGS. 24-27, where FIGS. 24 and 25 are the layout 2400 of the seven-segment AMOLED design, and layout 2500 of the 4×6 pixel array design, respectively. FIG. 26 is a photograph 2600 showing the transparent AMOLED circuit fabricated on glass. A schematic 2700 of the expected output from seven-segment and 4×6 pixel array AMOLED circuit is shown in FIG. 27.

Only a few embodiments are described for wafer-scale processing of SN-TFT for display applications, including wafer-scale assembly or network of high density, uniform separated nanotube networks; high-yield fabrication of devices with good performance, and proof of concept demonstration of OLED switching controlled by a SN-TFT. The APTES assisted solution based assembly or network of separated nanotube thin-film has been achieved on complete 3 inch Si/SiO₂ wafers, followed by the fabrication to yield transistors with high yield (>98%), small sheet resistance (˜25 kΩ/sq), high current density (˜10 μA/μm), high mobility (˜52 cm²V⁻¹s⁻¹) and good on/off ratio (>10⁴). In addition, OLED control circuit has been demonstrated with the SN-TFT, and the modulation in the output light intensity exceeds 10⁴. This demonstration can provide guide to future research on SN-TFT based display electronics such as active matrix organic light-emitting diode (AMOLED). Described are significant advancements toward the challenging task of large scale separated nanotube thin-film assembly or network and solutions to the problem of co-existence of both metallic and semiconductive nanotubes in the state-of-the-art nanotube transistor fabrication techniques.

In another aspect, techniques, systems, apparatus and materials are described for air-stable conversion of separated carbon nanotube thin-film transistors from P-type to N-type using atomic layer deposition of high-k oxide and its application in CMOS digital circuits. Fabricated based on techniques of carbon nanotube separation, pre-separated, high purity semiconducting carbon nanotubes have various applications. Due to their extraordinary electrical property, pre-separated carbon nanotubes hold great potential for thin-film transistors (TFTs) and integrated circuit applications. Described is fabrication of air-stable N-type thin-film transistors with industry compatible techniques. For example, described is a method of converting the as-made P-type separated nanotube thin film transistors (SN-TFTs) into N-type transistors by adding a high-K oxide layer on top of the device using atomic layer deposition (ALD) and its application in CMOS macroelectronic digital circuits. The adsorption of oxygen and accumulation of fixed charge in the nanotube and dielectric layer interface during the ALD process can be proved to be the reasons of this carrier type conversion by designed experiments. The N-type devices exhibit comparable electrical performance as the P-type devices in terms of on-current, on/off ratio and device mobility. A CMOS inverter with rail to rail output, symmetric input/output behavior and large noise margin are also demonstrated. The excellent performance enables the feasibility of cascading multiple stages of logic blocks and larger scale integration. The described approach can serve as the critical foundation for future nanotube-based thin-film macroelectronics.

Because of the extraordinary electrical properties such as high intrinsic carrier mobility and current-carrying capability, carbon nanotubes have been used extensively to demonstrate all kinds of electrical components including ballistic and high mobility transistors, radio frequency devices and integrated logic circuits such as inverters and ring-oscillators. Besides, thin-films of single-walled carbon nanotubes achieved using either solution based filtration or chemical vapor deposition (CVD) method also shows great potential as channel material for thin-film transistors (TFTs). Carbon nanotube based TFTs have the advantages of room-temperature processing compatibility, transparency, flexibility, as well as high device performance compared with other popular TFT channel materials such as amorphous poly-silicon or organic materials. Considerations for carbon nanotube based TFTs include the co-existence of metallic and semiconducting nanotubes and the lack of a stable way to obtain N-type TFTs. Admixture of metallic nanotubes can lead to low on/off current ratios and the absence of N-type TFTs can limit the transistor application in large scale digital integrate circuits.

As described above, the semiconducting nanotubes can be separated from the metallic ones using density gradient ultracentrifugation. Also as described above, based on the separated nanotubes, TFTs with high performance can be implemented (e.g., by using evaporation self-assembly or network method³³ and using the solution-based aminosilane assisted wafer-scale separated nanotube deposition technique.)

Described below are techniques, systems, apparatus and materials for obtaining stable N-type devices. Although N-type transistors can be achieved by chemical doping or using metals with low work function such as Gd, Sc or Y as contacts, these devices are either not stable in air or difficult to reproduce. Alternatively, HfO₂ passivation layer deposited using ALD can be used to convert individual nanotube transistors to N-type. This can be extended and modified to the nanotube TFT devices. For example, N-type SN-TFTs can be obtained by adding high-K oxide passivation layer. Other than HfO₂, other materials can be used to deposit a passivation layer. Described below are the factors that can affect this carrier conversion process. This kind of N-type devices can offer good electric performance, and thus the techniques can be used in CMOS digital circuits.

For example, N-type SN-TFTs can be obtained by adding a high-K oxide layer to the nanotube surface using ALD and its applications in macroelectronic CMOS circuits are described. The described techniques, systems, apparatus and materials can include the following: (1) N-type SN-TFTs can be made by passivating the back-gated transistors using a high-K oxide layer; (2) The mechanism of this carrier type conversion can be studied and tested by a series of experiments; (3) various, e.g., 400 P-type and N-type SN-TFTs (200 without ALD layer, 100 with HfO₂ ALD and 100 with Al₂O₃ ALD) with various channel lengths and widths can be fabricated and measured. Key performance metrics such as on-current, on/off ratio and mobility of devices are systematically and directly compared; and (4) A CMOS inverter can be designed and made using almost symmetric P-type and N-type SN-TFTs. The designed inverter can achieve a maximum gain as high as 8.4 and can exhibit rail to rail output, symmetric input/output behavior and large noise margin which are crucial requirements for the cascading of multiple stages of logic blocks. Described CMOS SN-TFT platform shows significant advantages over conventional platforms with respect to stability, scalability, reproducibility and device performance, and suggests a practical and realistic approach for nanotube based macroelectronic integrated circuit applications.

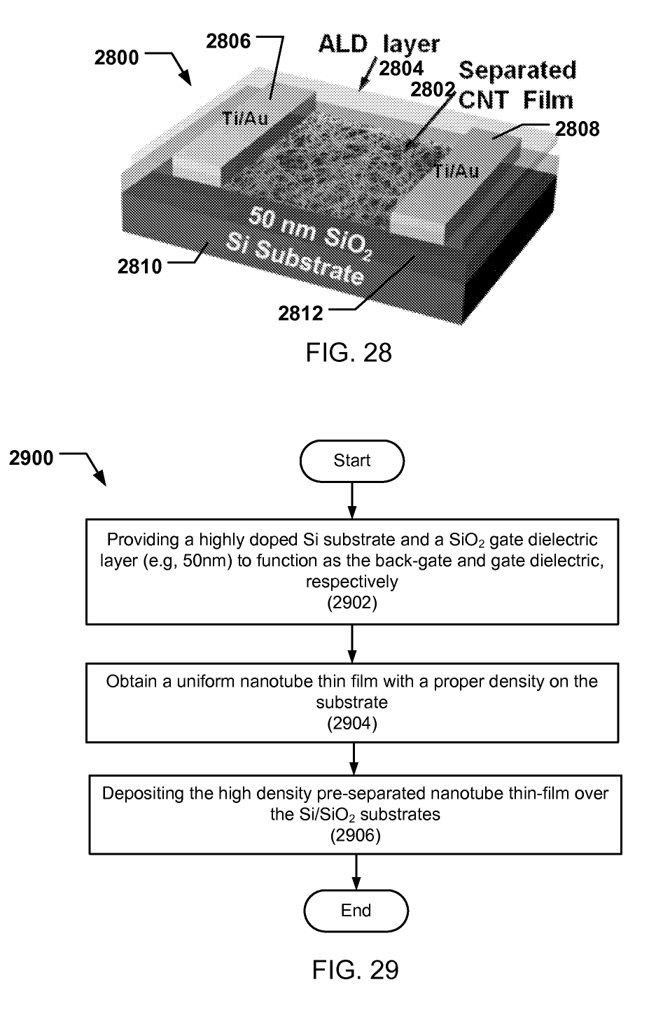

FIG. 28 illustrates an N-type SN-TFTs device structure 2800. The N-type back-gated SN-TFT structure 2800 includes a silicon substrate layer 2810 with a SiO₂ (e.g., 50 nm) gate dielectric layer disposed over the substrate. The N-type SN-TFTs device also includes a passivation layer 2804 (e.g., using ALD) and a separated carbon nanotube thin film layer 2802. The N-type SN-TFTs device also includes Ti/Au (e.g., 5 Å/50 nm) contacts 2806 and 2808.

FIG. 29 is a process flow diagram of a process 2900 for fabricating an N-type SN-TFTs device. A highly doped Si substrate and a SiO₂ gate dielectric layer (e.g., 50 nm) can be provided to function as the back-gate and gate dielectric, respectively (2902). Solution-based aminosilane assisted separated nanotube deposition technique described above can be used to obtain a pre-separated uniform nanotube thin-film with a proper high density on the substrate (2904). The high density pre-separated nanotube thin-film 2802 is deposited over the Si/SiO₂ substrates (2906). For example, a high density, uniform 98% pre-separated nanotube thin-film can be deposited onto the Si/SiO₂ substrates using the separated semiconducting nanotubes (IsoNanotubes-S™) from NanoIntegris, Inc.

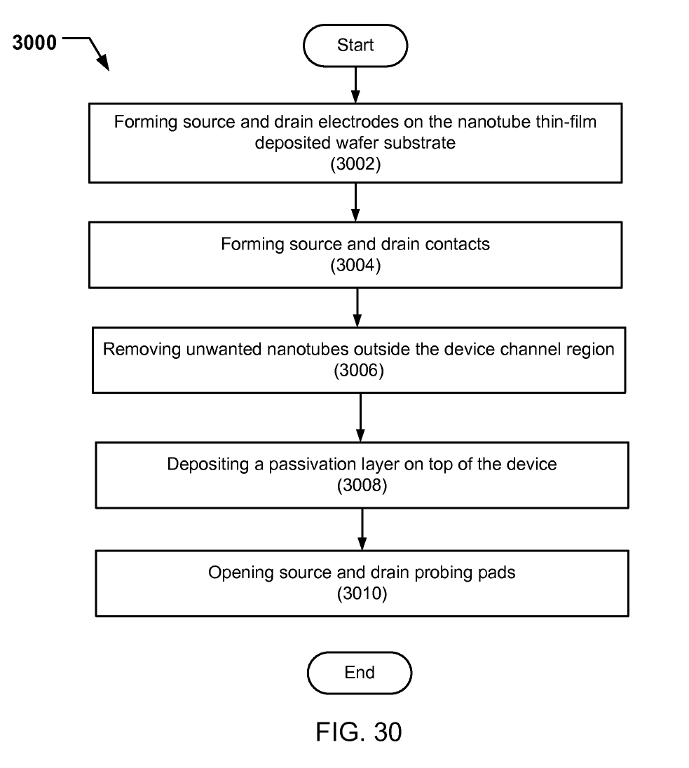

Following the nanotube deposition process is a device fabrication process as shown in the process flow diagram 3000 of FIG. 30. The source and drain electrodes are formed on the nanotube thin-film deposited wafer substrate (3002). For example, the source and drain electrodes can be patterned by photo-lithography. Source and drain contacts are formed (3004). For example, 5 Å Ti and 50 nm Au can be deposited followed by a lift-off process to form the source and drain metal contacts. Au can be used as the source and drain contact mainly because its work function (5.1 eV) and stability. The work function of Au gives similar Schottky barrier (SB) for electrons and holes and makes it possible to fabricate P-type and N-type SN-TFTs with symmetric device performance. Additionally, the stability of Au ensures that this approach is air stable and reproducible.

After source and drain patterning, unwanted nanotubes outside the device channel region are removed (3006). Because the separated nanotube thin-film cover the entire wafer, in order to achieve accurate channel length and width and to remove the possible leakage in the devices, one more step of photo-lithography plus O₂ plasma can be used to remove the unwanted nanotubes outside the device channel region. A passivation layer is deposited on top of the device (3008). For example, HfO₂ passivation layer can be deposited on top of the device using ALD at 250° C. The source and drain probing pads are opened, for example, by photo-lithography and wet etching (3010).

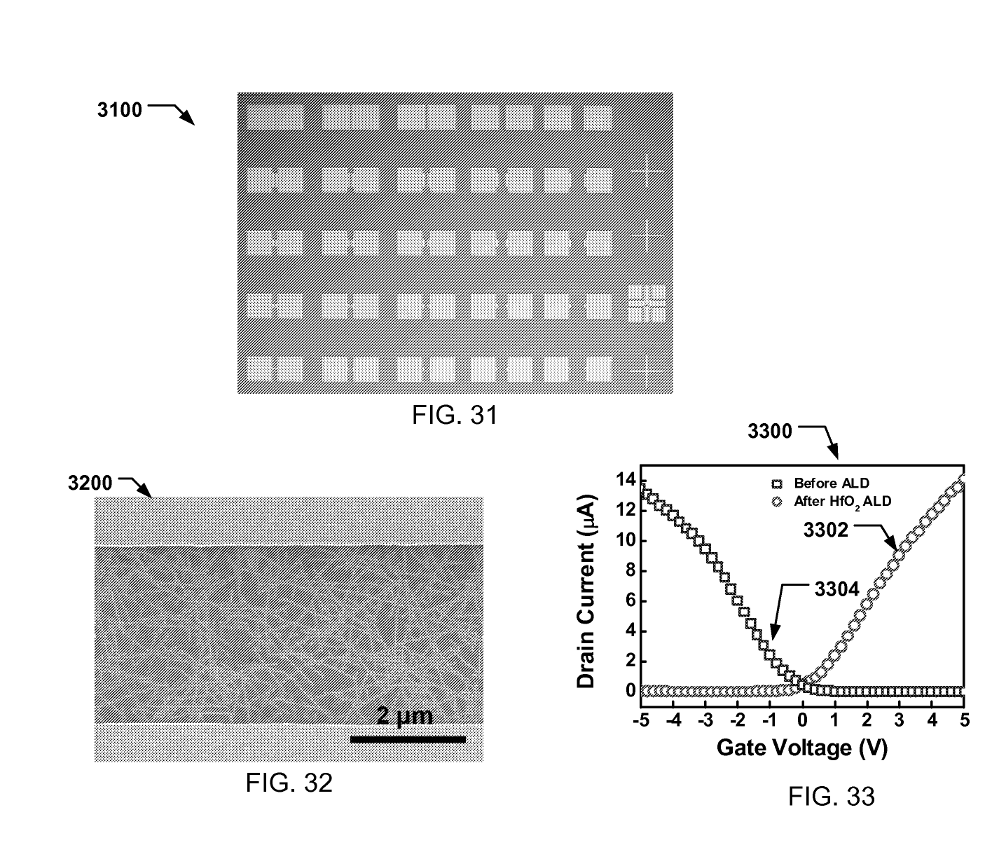

FIG. 31 is a photograph 3100 of an array of devices after fabrication. The array can include or consist of SN-TFTs with channel width (W) of 10, 20, 50, 100, and 200 μm, and channel length (L) of 5, 10, 20, 50, and 100 μm.

Field-emission scanning electron microscope (FE-SEM) can be used to inspect the device after source drain patterning and the channel of a typical SN-TFT with 5 μm channel length is shown in the image 3200 of FIG. 32. The image 3200 shows that the channel includes or consists of uniform and dense nanotube thin-film due to the effort of APTES assisted deposition. The average nanotube density is measured to be 46 tubes/μm², for example.

The electrical performance of the SN-TFTs can be characterized as shown in FIG. 33. The transfer characteristics (I_{D}-V_{G}) 3300 of a typical device is shown in FIG. 33 before (blue 3304) and after (red 3302) HfO₂ deposition. These two curves 3304 and 3302 are from the same device with a channel length of 5 μm and channel width of 200 μm. The data plotted in FIG. 33 shows that the device shows perfectly symmetric behavior in terms of on-current, transconductance and threshold voltage before and after adding the ALD layer. Additionally, the on/off ratio of the device does not change too much and both ratios are higher than 10⁴ (before ALD 2.24×10⁶, after ALD 7.79×10⁵). The use of Au electrodes may be one of the main reasons for the symmetric electrical performance. SN-TFTs with Pd contact can be used also, as Pd is well known for forming ohmic contact for P-type nanotube device due to its large work function. The SN-TFTs with Pd contact have a much higher P-type on-current before ALD passivation layer than the N-type on-current after ALD. Rather than a predominant N-type behavior, the SN-TFTs with Pd contact shows ambipolar transfer characteristic with the N-branch on-current about 5 times larger than the P-branch on-current.

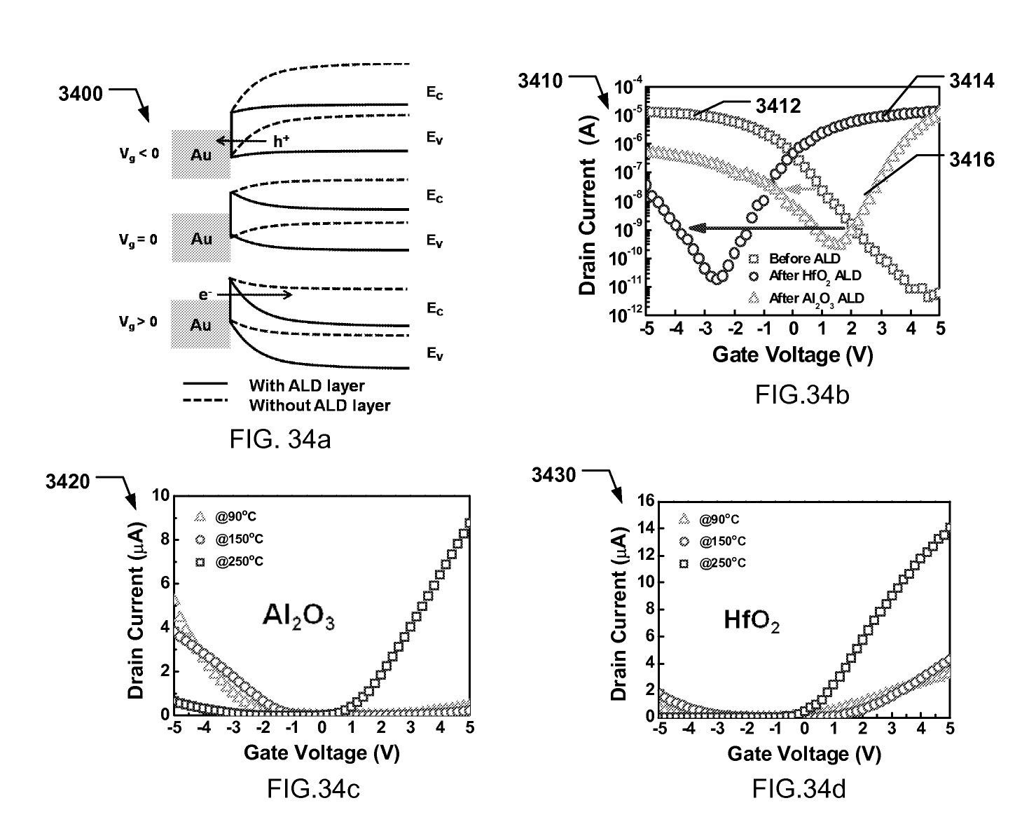

Two potential key factors for the conversion from pristine P-type SN-TFTs to N-type by this ALD high-K oxide layer can include: (1) The baking processing in the vacuum chamber during the ALD process; and (2) The positive fixed charge in the high-K oxide layer introduced due to the deficiency of oxygen atoms. As known, the intrinsic carbon nanotubes have the same predilection for electrons and holes which means that the intrinsic nanotube device should exhibit ambipolar transistor behavior. However, the adsorption of moisture in ambient and the work function of the contact metal can affect the electrical property of the device. For devices with Au contact, it gives Schottky barrier for both electrons and holes but because of the adsorbed moisture and oxygen molecules, some equivalent negative charge can be stored near the source and drain contact in the channel, which can bend the energy band upwards and reduce the SB width for holes. FIG. 34a is a diagram 3400 showing a mechanism of an N-type SN-TFT by ALD high-K oxide layer with a band structure of a nanotube-metal contact with (solid line) and without (dash line) ALD layer at different gate voltages (V_{G}>0 V, V_{G}=0 V and V_{G}<0 V). The bended band structure at different gate voltage is shown in the diagram 3400 of FIG. 34a as the dash line. When a negative gate voltage is applied to the device, the energy band can be bended upwards even further. When the SB is thin enough, holes can tunnel through and the transistor is turned on. Contrarily, when a positive voltage is applied to the gate, the energy band can be flattened which increases the barrier for holes putting the transistor into OFF state. So because of the oxygen, the SN-TFTs with Au contact in ambient show P-type transistor behavior.

During the ALD process, the device can be baked at 250° C. in an evacuated chamber with a pressure of 0.3 Torr for about 30 min. Moisture and oxygen near the nanotube surface are driven away and desorbed during the ALD process. In the same time the high-K oxide layer is deposited on top to passivate the device, which can prevent the moisture from adsorbing on the nanotube again and make the nanotube become intrinsic. Moreover, positive a fixed charge can also be introduced into the nanotube-SiO₂ interface during the ALD process, which may be due to the deficiency of oxygen atoms in the oxide layer. This positive fixed charge can play a similar role as the negative charge caused by the oxygen. As the polarity of the charge is changed, instead of increasing the hole conductance, it may increase the electron conduction by bending the energy band near the metal contact downwards. This is also shown in FIG. 34a as the solid line. The energy band shows that the transistor can be turned on when gate voltage is positive and turned off when it is negative, i.e. the N-type transistor behavior.

This mechanism can also be explained by the shift of the intrinsic ambipolar transfer characteristic, which could be characterized by the change of the flat band voltage (V_{FB}) of the device. Effectively, by adding the high-K oxide passivation layer, the fixed charge in the interface is increased by a amount of ΔQ_{f} (e.g., from negative charge to positive charge). As

$${V}_{FB} = {φ}_{ms} - \frac{{Q}_{f}}{{C}_{ox}} ,$$

where φₘₛ is the work function difference between metal contact and nanotube and Cₒₓ is the dielectric capacitance per unit area, by increasing the fixed charge, the V_{FB} decrease, which means the transfer characteristic is shifted to the left. By doing so, the N-branch of the ambipolar behavior is moved into the sweeping window of gate voltage which is concerned (ex. −5V˜5V here). This leads to the N-type transistor behavior after adding the ALD passivation layer.

To illustrate the mechanism of the P-type to N-type conversion by the ALD high-K oxide layer, a series of experiment is designed and carried out as described below. Two P-type SN-TFTs with the same geometry and similar electrical performance are selected and allowed to go through ALD with different high-K materials—HfO₂ and Al₂O₃. The HfO₂ ALD process introduces more positive charge into the SiO₂-nanotube interface than the Al₂O₃ ALD process. Based on the described techniques, systems, apparatus and materials, a larger shift should be observed from the device with HfO₂ ALD than the device with Al₂O₃ ALD. The transfer characteristics 3410 of these two devices before and after ALD are measured and shown in logarithm scale in FIG. 34b. Data curve 3412 represents the transfer characteristics before ALD. Data curves 3414 and 3416 represent the transfer characteristics after HfO₂ ALD and Al₂O₃ ALD respective. The result is in accordance with the predicted transistor behavior which is a good support for the described techniques, systems, apparatus and materials. Moreover, FIG. 34b shows that the shape of the P-branch of the device after high-K oxide layer ALD is very similar to the P-type transistor transfer characteristics before ALD, which is also a very strong evidence that the N-type transistor behavior results from the shift of the intrinsic ambiploar behavior of SN-TFT due to the increase of interface fixed charge.

To show that moisture and oxygen is indeed driven away by the ALD process, the temperature dependence of the described ALD N-type SN-TFTs is described. ALD of HfO₂ and Al₂O₃ are carried out with different temperatures (90° C., 150° C. and 250° C.) onto the SN-TFTs. The transfer characteristics 3420 and 3430 for ALD of HfO₂ and Al₂O₃ are plotted in FIGS. 34c and 34d respectively. The curves clearly reveal the temperature dependence of this ALD N-type method. At low temperatures, the devices show ambipolar (with HfO₂ ALD) or even P-type (with Al₂O₃ ALD) transistor behavior. As the temperature increases, the P-branch on-current decreases while the N-branch on-current increases and the two kinds of devices are all turned into N-type at the temperature of 250° C. This temperature dependence phenomenon is again a good support of the described techniques, systems, apparatus and materials. Namely, the different temperature can affect the driving away of the moisture. By increasing the temperature, more moisture and oxygen can be driven away and desorbed during the deposition of the high-K oxide, which can equivalently increase the electron conduction, decrease the hole conduction and make the device more N-type.

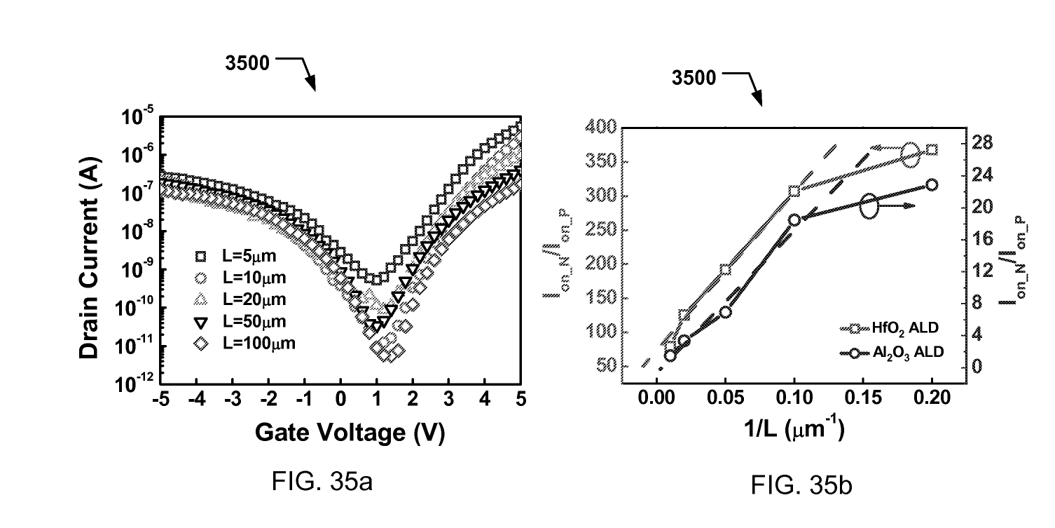

Additionally, the channel length dependence of the ratio between the N-branch on-current (Iₒₙ_{_{—}}_{N}) and P-branch on-current (Iₒₙ_{_{—}}_{P}) of one device after ALD is described. As the channel length increases, the ratio Iₒₙ_{_{—}}_{N}/Iₒₙ_{_{—}}_{P} can decrease which means the transfer curves of the SN-TFTs after ALD can change from predominant N-type transistor behavior to almost ambipolar behavior. This phenomenon is illustrated in FIG. 35a, where devices with the same channel width (W=100 μm) and different channel length (L=5, 10, 20, 50, and 100 μm) are passivated with ALD of Al₂O₃at 250° C. FIG. 35a shows a drain current-gate voltage relationship 3500. In order to obtain a better understanding of this channel length dependence, multiple (e.g., 200) devices (e.g., 100 with ALD of HfO₂, and the other 100 with ALD of Al₂O₃) can be measured and the average ratios of Iₒₙ_{_{—}}_{N}/Iₒₙ_{_{—}}_{P} after ALD (3500) are summarized in FIG. 35b. The average ratios 3500 shown in FIG. 35b indicates that the two kinds of the devices (e.g., HfO₂ ALD and Al₂O₃ALD) have similar channel length dependence but devices with HfO₂ ALD have a much high Iₒₙ_{_{—}}_{N}/Iₒₙ_{_{—}}_{P} ratio than the one with Al₂O₃ALD. Also, when L is larger than 10 μm, Iₒₙ_{_{—}}_{N}/Iₒₙ_{_{—}}_{P} follows a linear relationship with 1/L.

This channel length dependence of Iₒₙ_{_{—}}_{N}/Iₒₙ_{_{—}}_{P} can be attributed to the unique feature of the nanotube network which is percolation. Unlike aligned or single nanotube devices, nanotube percolation is happening inside the channel of SN-TFTs. This gives considerable channel resistance (R_{ch}) for SN-TFTs which use nanotube network as the channel material. In addition, as

$${R}_{ch} = {R}_{•} \frac{L}{W}$$

where R_{□} is the sheet resistance of the separated nanotube film with a typical value of 25 kΩ/sq³⁴, this resistance is directly proportional to the channel length (L). When a positive gate voltage is applied, the current is determined by the electron conductance (Gₑ) which is the inverse of the sum of channel resistance and contact resistance for electrons (R_{c}_{_{—}}ₑ). Alternatively, the electron conductance can be expressed as:

$${G}_{e} = \frac{1}{{R}_{ch} + {R}_{c \_ e}} .$$

Because this is an N-type device, R_{c}_{_{—}}ₑ is relatively small when the device is on, so when the channel length is long enough, R_{ch} will be much larger than R_{c}_{_{—}}ₑ. In another word,

$${G}_{e} \approx \frac{1}{{R}_{ch}}$$

and

$${I}_{on \_ N} = {G}_{e} \cdot {V}_{DS} \approx \frac{{V}_{DS}}{{R}_{ch}} = \frac{{V}_{DS} W}{{R}_{•} L}$$

which means Iₒₙ_{_{—}}_{N} proportional to 1/L. On the other hand, when the gate voltage is negative, the conductance for holes (Gₕ) can be written as

$${G}_{e} = \frac{1}{{R}_{ch} + {R}_{c \_ h}} ,$$

where R_{c}_{_{—}}ₕ is the contact resistance for holes. For N-type devices, the contact resistance for holes is very large even with a negative V_{G} because of the SB, so

$${G}_{h} \approx \frac{1}{{R}_{c \_ h}} and {I}_{on \_ P} = {G}_{h} \cdot {V}_{DS} \approx \frac{{V}_{DS}}{{R}_{c \_ h}} .$$

As R_{c}_{_{—}}ₕ comes from the SB which is independent with L, Iₒₙ_{_{—}}_{P} will stay the same as L varies. The curves in FIG. 35a are consistent with the described analysis. As L increases from 5 μm to 100 μm, Iₒₙ_{_{—}}_{N} decreases by a factor of 100 while Iₒₙ_{_{—}}ₚ only varies by around 5 times, this leads to the drop of Iₒₙ_{_{—}}_{N}/Iₒₙ_{_{—}}_{P} ratio.

From the above result, the equation for the ratio of Iₒₙ_{_{—}}_{N}/Iₒₙ_{_{—}}_{P} can be derived, which is

$${I}_{on \_ N} / {I}_{on \_ P} = \frac{{G}_{e} \cdot {V}_{DS}}{{G}_{h} \cdot {V}_{DS}} = \frac{{G}_{e}}{{G}_{h}} = \frac{{R}_{c \_ h} W}{{R}_{•} L} .$$

Therefore, if W is fixed and L is long enough, the ratio is inversely proportional to L and also is affected by the SB for holes. FIG. 35b supports these findings, the Iₒₙ_{_{—}}_{N}/Iₒₙ_{_{—}}_{P} ratio is changing linearly with the L⁻¹ for long channel length devices (L>10 μm) and devices covered by HfO₂ have higher Iₒₙ_{_{—}}_{N}/Iₒₙ_{_{—}}_{P} ratio than the one covered by Al₂O₃ because of the higher contact resistance for hole at this gate voltage. For the devices with shorter channel lengths, the channel resistance is small and comparable to the contact resistance for electrons. Therefore, both of these resistances should be considered when calculating Iₒₙ_{_{—}}_{N}, and then Iₒₙ_{_{—}}_{N}/Iₒₙ_{_{—}}_{P} ratio of the shorter channel length device is lower than the ideal case which is shown as the data point of the devices with channel length of 5 μm in FIG. 35b. In summary, in order to obtain a perfect N-type behavior transistor which is important for integrate circuit applications as it can affect the static power consumption, shorter channel length and HfO₂ ALD is needed.

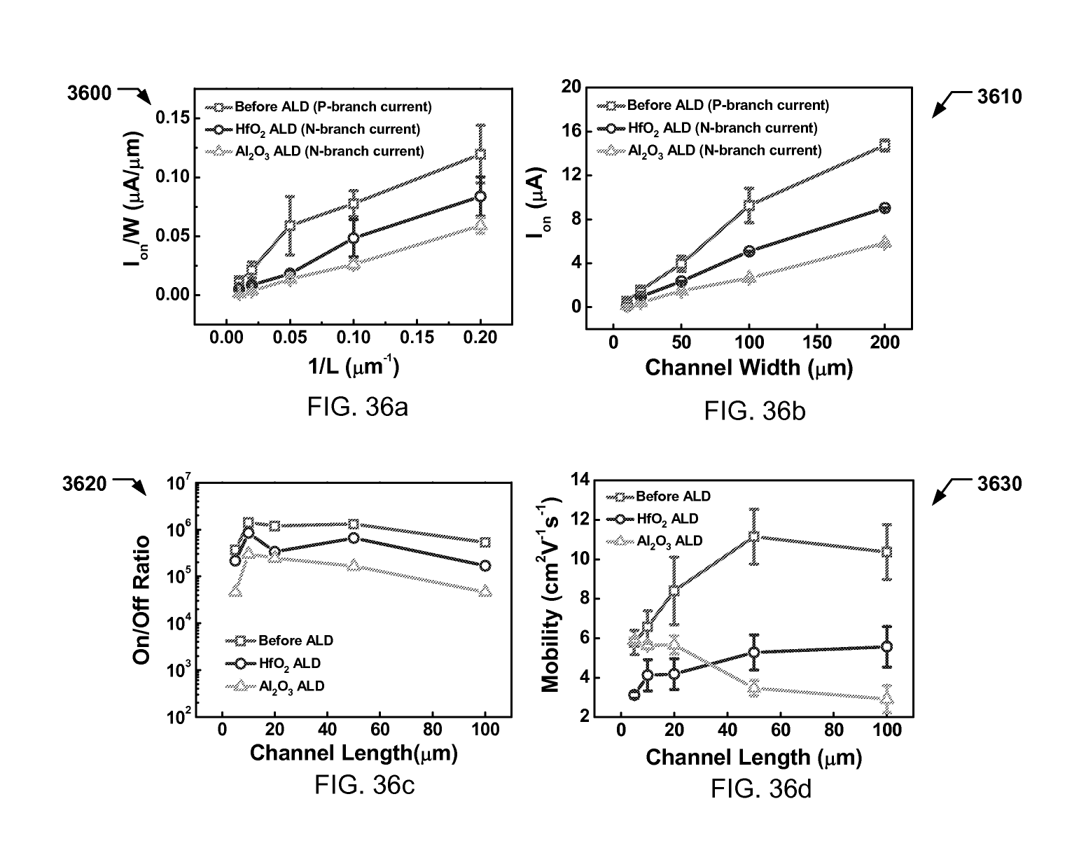

Additionally, the potential key device performance metrics such as on-current density, on/off ratio and device mobility for P-type and N-type SN-TFTs are described. FIGS. 36a-d summarize the results of the measurement of 200 pristine SN-TFTs with various channel lengths and channel widths before and after adding ALD high-K oxide layer. Out of the devices measured, 100 of them are converted to N-type SN-TFTs by adding HfO₂ ALD layer and others are by adding Al₂O₃ ALD layer.

FIG. 36a exhibits the normalized on-current densities (Iₒₙ/W) 3600 of the transistors with various channel lengths and channel width measured at V_{D}=1 V, V_{G}=5 V for N-type SN-TFTs and −5 V for P-type SN-TFTs. The data shown in FIG. 36a indicates that the on-current density is approximately inversely proportional to the channel length for all three kinds of SN-TFTs. For N-type SN-TFTs, this obeys the equation derived for N-branch on-current above. On the other hand, for the P-type transistors, the linear relationship between on-current and L⁻¹ can be derived following the described analysis for N-type transistors by just changing the current carrier from electrons to holes. No significant degradation is detected in the device on-current after ALD. The highest on-current density from P-type SN-TFTs is measured to be 0.12 μA/μm, slightly higher than the one from N-type SN-TFTs by ALD of HfO₂ (0.084 μA/μm) and Al₂O₃ (0.060 μA/μm). All values are achieved in devices with 5 μm channel length. Comparing the data for transistors before and after conversion, P-type and N-type SN-TFTs are shown to have comparable average on-current density (although the one for P-type device is a little bit higher on average.)

The relationship between average on-current and channel width (3610) is also measured and plotted in FIG. 36b. The data is achieved from devices with channel length of 10 μm at the same bias voltage as mentioned above. All three curves in FIG. 36b show highly linear relationship which illustrates the uniformity of the separated nanotube thin-film. Similar with the results in FIG. 36a, P-type SN-TFTs exhibit a little bit higher on-current than the N-type SN-TFTs. Additionally, both of the measurement results in FIGS. 36a and 36b exhibit very small error bar, indicating again the highly uniform nature of the SN-TFTs.

Moreover, the on/off ratios (3620) of the N-type and P-type SN-TFTs are described and illustrated in FIG. 36c. All three types of devices show on/off ratio higher than 10⁴ for all the channel length measured. This high on/off ratio can be important for digital applications, as the high on/off ratio helps to obtain rail-to-rail output which makes the circuit easier to achieve large noise margin. More importantly, the low off-state current can reduce the static power consumption. The on/off ratio is expected to increase as the channel length increases because of the reduction of the probability of percolative transport through metallic nanotube networks. Here as 98% semiconducting nanotubes are used, the probability of percolative transport through metallic nanotube networks is almost eliminated even for the shortest channel length of 5 μm. As shorter channel length devices also exhibit higher on-current, better N-type device behavior and requires less area, this high on/off ratio property makes it more attractive for integrate circuit applications. In addition, the device on/off ratio stays almost the same before and after ALD process, which ensures that the N-type device obtained from this technology can be used in nanotube CMOS circuit fabrication. The slightly decrease of on/off ratio for longer channel length device is not ascribable to the real device performance but to the measurement limit of the instrument. It is because when the channel is very long, the on-current decreases while the off current is too small to be measured precisely by our equipment (HP 4145B Semiconductor Parameter Analyzer with an accuracy of 1 pA).

Besides the on-current and on/off ratio, device mobility (μ_{device}) is also a very important parameter for SN-TFTs. The device mobility is described from devices with various channel length. The mobility can be extracted by the following equation:

$${μ}_{device} = \frac{L}{{V}_{D} {C}_{ox} W} \cdot \frac{d {I}_{d}}{d {V}_{g}} = \frac{L}{{V}_{D} {C}_{ox}} \cdot \frac{{g}_{m}}{W} \qquad ( 1 )$$

where L and W are the device channel length and width, Cₒₓ is the gate capacitance per unit area and gₘ is the device transconductance extracted from the maximum slope of the transfer characteristics measured at V_{D}=1 V. Because of the one dimensional property of nanotubes, electrostatic coupling between nanotubes should be considered when calculating the gate capacitance. The equation for the gate capacitance can be written as:^{42,43}

$${C}_{ox} = {\{ {C}_{Q}^{- 1} + \frac{1}{2 {πɛ}_{0} {ɛ}_{ox}} ln [ \frac{{Λ}_{0}}{R} \frac{sinh ( 2 π {t}_{ox} / {Λ}_{0} )}{π} ] \}}^{- 1} {Λ}_{0}^{- 1} \qquad ( 2 )$$

where 1/Λ₀ stands for the density of nanotubes and is measured to be around 10 tubes/μm, C_{Q}=4.0×10⁻¹⁰ F/m is the quantum capacitance of nanotubes, tₒₓ=50 nm is the thickness of the dielectric layer, R=1.2 nm is measured to be the average radius of nanotubes, and ε₀εₒₓ=3.9×8.85×10⁻¹⁴ F/cm is the dielectric constant at the interface where the nanotubes are placed. Based on Equation 2, it can be determined that Cₒₓ=3.46×10⁻⁸ F/cm².

Using Equation 1 and the transconductance derived from the transfer characteristics, the devices mobility of the SN-TFTs can be determined, and the data is summarized in FIG. 36d. The mobility for P-type devices and N-type devices with HfO₂ ALD increases as channel length increases. This can be attributed to the idea that the Au contacts result in large Schottky barriers, so the device mobility is likely to be limited by the metal/nanotube contacts, similar to the case for aligned nanotube transistors. As the channel length increases, the effect of metal/nanotube contacts become less significant and the mobility increases. Additionally, for N-type SN-TFTs with Al₂O₃, the mobility reduces when the channel length increases. The reason for the decrease may be attributed to the idea that the mobility for these devices is dominant by nanotube percolation effect rather than contact effect. The highest mobility of P-type SN-TFTs, N-type SN-TFTs with HfO₂ and Al₂O₃ is 11 cm²V⁻¹s⁻¹, 5.6 cm²V⁻¹s⁻¹ and 5.9 cm²V⁻¹s⁻¹ respectively, all of these are much higher than the typical mobility for amorphous silicon (0.4 cm²V⁻¹s⁻¹) and organic materials (0.02 cm²V⁻¹s⁻¹).

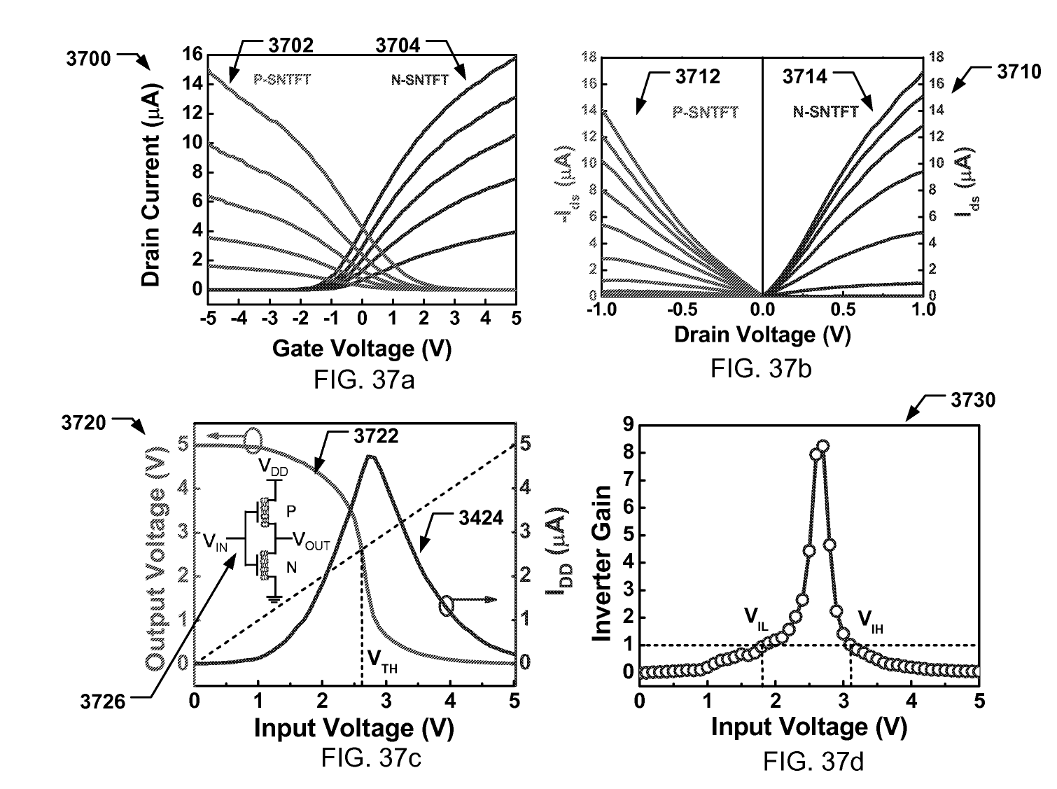

Our ability to fabricate high performance, uniform, high on/off ratio N-type and P-type SN-TFTs enable further exploration of their applications in CMOS digital circuits. Compared with PMOS only digital circuit, CMOS structure has a lot of advantages such as rail-to-rail output, smaller fall time and most importantly, much lower static power consumption. For illustrative purposes, a basic digital functional block, CMOS inverter is described. First two typical P-type and N-type SN-TFTs are selected with the same channel geometry (L=5 μm, W=200 μm) and their transfer (I_{D}-V_{G} curves 3700) and output (I_{D}-V_{D} curves 3710) characteristics are measured as shown in FIGS. 37a and 37b, respectively. The data for the I_{D}-V_{G} curves 3700 is achieved with V_{D} from 0.2 V to 1 V with a step of 0.2 V. The I_{D}-V_{G} curves for P-SNTFT devices are labeled 3702, and the I_{D}-V_{G} curves for the N-SNTFT devices are labeled 3704 in FIG. 37a. For I_{D}-V_{D} curves 3710, the gate voltage is varied from −5 V to 5V with a step of 1 V. The I_{D}-V_{D} curves for P-SNTFT devices are labeled 3712, and the I_{D}-V_{D} curves for the N-SNTFT devices are labeled 3714 in FIG. 37b. The two transistors exhibit almost perfectly symmetric electrical performance, which ensures that the inverter threshold voltage (V_{TH}, defined by the input voltage when it equals to the output voltage) will be around one half of the supply voltage and the noise margin for logic “0” and “1” is similar and maximized.

Following the individual device measurement, the two transistors are connected into a CMOS inverter by probe station according to the schematic in FIG. 37c inset 3726. The inverter voltage 3722 and current 3724 transfer characteristics are plotted in FIG. 37c. The inverters work with a V_{DD} of 5V and as expected, it exhibits symmetric input/output behavior with rail-to-rail output and the inverter threshold voltage is measured to be 2.6 V, almost one half of the supply voltage (V_{DD}/2=2.5V). Also, the current is zero when the output reaches its boundary meaning that the power consumption is zero as long as the inverter stays in “0” or “1” state. In addition, by taking the derivative of the voltage transfer curve, the information about the gain 3730 of the inverter can be obtained as illustrated in FIG. 37d. The highest gain of the inverter is calculated to be 8.4 achieved at an input voltage of 2.7 V.

For digital circuits, other than the properties discussed above, there is one more parameter affecting the circuit performance which is the noise margin (NM). NM is important because it quantizes the external signal perturbation that a logic gate can withstand during operation. This tolerance ability to variations in the signal level is especially valuable for the circuit nowadays as the supply voltage is getting smaller and smaller while the parasitic effect is becoming more and more considerable. For a logic gate like an inverter, the noise margin is the minimum of two values: the noise margin for low signal levels (NM_{L}) and the noise margin for high signal levels (NM_{H}). Furthermore, NM_{L} is defined as the difference between maximum input voltage which can be interpreted as logic “0” (V_{IL}) and minimum output voltage when the output level is logic “0” (V_{OL}) or NM_{L}=V_{H}−V_{OL}. Similarly, NM_{H} is the difference between maximum output voltage when the output level is logic “1” (V_{OH}) and minimum input voltage which can be interpreted as logic “1” (V_{IH}) or NM_{H}=V_{OH}−V_{IH}·V_{IH} and V_{IL} are usually calculated as the input voltage when the inverter gain equals to 1. Therefore, from the gain curve plotted in FIG. 37d, it can be determined that for the described CMOS inverter, V_{IL}=1.8 V and V_{IH}=3.1 V. By definition, V_{OL} and V_{OH} here are 0 V and 5 V, respectively, so NM_{L} is calculated to be 1.8 V and NM_{H} to be 1.9 V. Accordingly, the noise margin for the inverter is 1.8 V. As the supply voltage is 5 V and V_{TH} is 2.6 V, a noise margin of 1.8 V reveals that the circuit has very strong noise tolerance ability and is easy to cascade with other logic blocks. The reason for such a large noise margin is because of the contribution of both the CMOS structure and symmetric transistor behavior.

Only a few embodiments have been described for a method to convert the SN-TFTs into air-stable N-type transistors by adding a high-K oxide layer on top of the device using ALD and its application in CMOS macroelectronic digital circuit. Additionally, it has been described that desorption of moisture and oxygen and accumulation of positive fixed charge in the nanotube dielectric layer interface cause the carrier type conversion. Also, the channel length dependence of the N-branch and P-branch on-current ratio (Iₒₙ_{_{—}}_{N}/Iₒₙ_{_{—}}_{P}) have been described and shown. Moreover, N-type devices achieved using the described ALD method have comparable electrical performance as the pristine P-type SN-TFTs in terms of on-current, on/off ratio and mobility, which is supported by the statistic study described. A CMOS inverter has been further demonstrated by using P-type and N-type SN-TFTs with symmetric transistor performance. The inverter exhibits rail-to-rail output, symmetric input/output behavior and large noise margin which allows the possibility of cascading multiple stages of logic gates. The described techniques, apparatus, systems and materials can be used to fabricate high performance air-stable N-type separated nanotube thin-film transistors and can provide numerous applications in future SN-TFT based CMOS integrated circuit.

While this specification contains many specifics, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, the separation of various system components in the embodiments described above should not be understood as requiring such separation in all embodiments.

Only a few implementations and examples are described and other implementations, enhancements and variations can be made based on what is described and illustrated in this application.

What is claimed is as described and shown in this application:

1. A method of fabricating a wafer-scale separated semiconducting nanotube network, comprising:
providing a wafer substrate and a dielectric layer disposed over the substrate;
functionalizing the cleaned surface of the wafer substrate by applying a solution comprising linker molecules terminated with amine groups;
assembling separated nanotubes over the functionalized surface by applying to the functionalized surface a separated nanotube solution that comprises semiconducting nanotubes; and
removing residual materials from the assembled separated nanotubes.

2. The method of claim 1, wherein the substrate comprises silicon, glass, or polyethylene terephthalate (PET).

3. The method of claim 1, wherein the dielectric layer comprises SiO₂, Al₂O₃, or HfO₂.

4. The method of claim 1, wherein the linker molecules terminated with amine groups comprise aminopropyltriethoxy silane (APTES).

5. A method of fabricating a separated semiconducting nanotube thin-film transistor device, comprising:
fabricating a wafer-scale separated semiconducting nanotube network comprising:
providing a wafer substrate and a gate dielectric layer disposed over the substrate,
cleaning a surface of the wafer substrate to cause the surface to become hydrophilic,
functionalizing the cleaned surface of the wafer substrate by applying a solution comprising linker molecules terminated with amine groups,
assembling separated nanotubes over the functionalized surface by applying to the functionalized surface a separated nanotube solution that comprises semiconducting nanotubes, and
removing residual materials from the assembled separated nanotubes; and
fabricating a transistor device using the wafer-scale semiconducting separated nanotube network, comprising:
forming source and drain electrodes on the wafer substrate having the wafer-scale semiconducting separated nanotube network,
forming source and drain metal contacts on the wafer substrate having the wafer-scale separated semiconducting nanotube network, and
removing unwanted separated nanotubes from the wafer substrate that are outside a channel region.

6. The method of claim 5, wherein the substrate comprises silicon, glass, or polyethylene terephthalate (PET).

7. The method of claim 5, wherein the gate dielectric layer comprises SiO₂, Al₂O₃, or HfO₂.

8. The method of claim 5, wherein the linker molecules terminated with amine groups comprise aminopropyltriethoxy silane (APTES).

9. The method of claim 5, wherein forming the source and drain electrodes comprises patterned the source and drain electrodes by photo-lithography.

10. The method of claim 5, wherein forming the source and drain metal contacts comprises forming the source and drain metal contacts by depositing metal followed by a lift-off process.

11. The method of claim 5, wherein removing the unwanted separated nanotubes comprises using photo-lithography and O₂ plasma to remove the unwanted separated nanotubes outside the channel region.

12. A separated semiconducting nanotube thin-film transistor device, comprising:
a wafer substrate and a gate dielectric layer, wherein a surface of the wafer substrate is hydrophilic and functionalized with linker molecules terminated with amine groups;
a network of separated nanotubes disposed over the functionalized surface of the substrate, wherein the network of separated nanotubes comprises semiconducting nanotubes;
source and drain electrodes formed on the wafer substrate; and
source and drain metal contacts formed on the wafer substrate.

13. The device of claim 12, wherein the substrate comprises silicon, glass, or polyethylene terephthalate (PET).

14. The device of claim 12, wherein the gate dielectric layer comprises SiO₂, Al₂O₃, or HfO₂.

15. The device of claim 12, wherein the linker molecules terminated with amine groups comprise aminopropyltriethoxy silane (APTES).

16. The separated nanotube thin-film transistor device of claim 12, wherein the network of the separated nanotubes covers the surface of the substrate except for an area outside a channel region.

17. A display system comprising:
a display control circuit comprising a separated semiconducting nanotube thin-film transistor device, wherein the separated semiconducting nanotube thin-film transistor device comprises:
a wafer substrate and a gate dielectric layer disposed over the substrate, wherein a surface of the wafer substrate is hydrophilic and functionalized with linker molecules terminated with amine groups;
a network of separated nanotubes disposed over the functionalized surface of the substrate, wherein the network of separated nanotubes comprises semiconducting nanotubes;
source and drain electrodes formed on the wafer substrate; and
source and drain metal contacts formed on the wafer substrate; and
an organic light-emitting diode display device connected to the display control circuit.

18. The display system of claim 17, wherein the substrate of the separated semiconducting nanotube thin-film transistor device comprises silicon, glass, or polyethylene terephthalate (PET).

19. The display system of claim 17, wherein the gate dielectric layer of the separated semiconducting nanotube thin-film transistor device comprises SiO₂, Al₂O₃, or HfO₂.

20. The display system of claim 17, wherein the linker molecules terminated with amine groups in the separated semiconducting nanotube thin-film transistor device comprise aminopropyltriethoxy silane (APTES).

21. A method of fabricating active matrix organic light-emitting diodes (AMOLED), comprising:
fabricating a wafer-scale separated semiconducting nanotube network comprising:
providing a wafer substrate and a gate dielectric layer deposited over the substrate,
cleaning a surface of the wafer substrate to cause the surface to become hydrophilic,
functionalizing the cleaned surface of the wafer substrate by applying a solution comprising linker molecules terminated with amine groups,
assembling a network of separated nanotubes over the functionalized surface by applying to the functionalized surface a separated nanotube solution that comprises semiconducting nanotubes, and
removing residual materials from the assembled separated nanotubes;
fabricating a transistor device using the wafer-scale separated semiconducting nanotube network, comprising:
forming source and drain electrodes on the wafer substrate having the wafer-scale separated semiconducting nanotube network,
forming source and drain metal contacts on the wafer substrate having the wafer-scale separated semiconducting nanotube network, and
removing unwanted separated nanotubes from the wafer substrate that are outside a channel region; and
integrating multiple transistor devices and OLEDs to form pixel arrays.

22. The method of claim 21, wherein the substrate of the separated semiconducting nanotube thin-film transistor device comprises silicon, glass, or polyethylene terephthalate (PET).

23. The method of claim 21, wherein the gate dielectric layer of the separated semiconducting nanotube thin-film transistor device comprises SiO₂, Al₂O₃, or HfO₂.

24. The method of claim 21, wherein the linker molecules terminated with amine groups in the separated semiconducting nanotube thin-film transistor device comprise aminopropyltriethoxy silane (APTES).

25. The method of claim 21, wherein fabricating the wafer-scale separated nanotube network comprises providing an Indium-Tin-Oxide (ITO) layer as a back-gate for the transistor devices and an anode electrode for the OLEDs.

26. The method of claim 25, further comprising opening vias on top of the anode of the OLEDs, wherein the vias provide electrical paths between the ITO layer and metal interconnects.

27. The method of claim 21, wherein depositing the gate dielectric layer comprises depositing Al₂O₃ by atomic layer deposition (ALD).

28. The method of claim 21, further comprising depositing a SiO₂ layer as a passivation layer for the OLEDs.

29. An active matrix organic light-emitting diode (AMOLED) device, comprising:
pixel arrays, comprising:
separated semiconducting nanotube transistors; and
OLEDs integrated with the separated semiconducting nanotube transistors,
wherein the separated semiconducting nanotube transistors comprise:
a back-gate for the separated semiconducting nanotube transistors and an anode for the OLEDs;
a gate dielectric layer deposited by atomic layer deposition (ALD); and
separated semiconducting nanotubes deposited onto the ALD deposited gate dielectric layer.

30. The AMOLED device of claim 29, wherein the separated nanotubes are deposited over a surface of a substrate functionalized with linker molecules terminated with amine groups.

31. The AMOLED device of claim 30, wherein the linker molecules terminated with amine groups comprise aminopropyltriethoxy silane (APTES).

32. The AMOLED of claim 29, wherein the back gate comprises an Indium-Tin-Oxide (ITO) layer.

33. The AMOLED of claim 29, further comprising vias opened on top of the anode of the OLED to provide an electrical path between the back gate and metal interconnects.

34. The AMOLED of claim 29, further comprising a passivation layer for OLED deposition.

35. A method of fabricating an N-type separated semiconducting nanotube transistor device, comprising:
providing a wafer substrate comprising a back-gate layer and a gate dielectric layer;
functionalizing a surface of the substrate using linker molecules terminated with amine groups;
assembling a network of separated semiconducting nanotubes over the functionalized surface;
forming source and drain electrodes on the separated semiconducting nanotube network;
forming source and drain metal contacts by metal deposition followed by a lift-off process;
removing unwanted separated nanotubes outside a channel region; and
depositing a passivation layer over the wafer substrate.

36. The method of claim 35, wherein the substrate comprises silicon, glass, or polyethylene terephthalate (PET).

37. The method of claim 35, wherein the back-gate layer comprises silicon, glass, or polyethylene terephthalate (PET).

38. The method of claim 35, wherein the gate dielectric layer comprises SiO₂, Al₂O₃, or HfO₂.

39. The method of claim 35, wherein the linker molecules terminated with amine groups comprise aminopropyltriethoxy silane (APTES).

40. The method of claim 35, wherein removing the unwanted separated nanotubes comprises using photo-lithography and O₂ plasma to remove the unwanted separated nanotubes outside the device channel region.

41. The method of claim 35, wherein depositing the passivation layer comprises depositing a HfO₂ or Al₂O₃ passivation layer using atomic layer deposition (ALD).

42. The method of claim 35, further comprising opening source and drain probing pads by photo-lithography and wet etching.

43. An N-type separated semiconducting nanotube transistor device, comprising:
a wafer substrate comprising a back-gate layer and a gate dielectric layer, wherein a surface of the substrate is functionalized using linker molecules terminated with amine groups;
a network of separated semiconducting nanotubes assembled over the functionalized surface;
source and drain electrodes patterned on the separated semiconducting nanotube network;
source and drain metal contacts formed on the substrate; and
a passivation layer deposited over the wafer substrate.

44. The N-type separated semiconducting nanotube transistor device of claim 43, wherein the substrate comprises silicon, glass, or polyethylene terephthalate (PET).

45. The N-type separated semiconducting nanotube transistor device of claim 43, wherein the back-gate layer comprises silicon, glass, or polyethylene terephthalate (PET).

46. The N-type separated semiconducting nanotube transistor device of claim 43, wherein the gate dielectric layer comprises SiO₂, Al₂O₃, or HfO₂.

47. The N-type separated semiconducting nanotube transistor device of claim 43, wherein the linker molecules terminated with amine groups comprise aminopropyltriethoxy silane (APTES).

48. The N-type separated nanotube transistor device of claim 43, wherein the passivation layer comprises a HfO₂ or Al₂O₃ passivation layer.

49. The N-type separated nanotube transistor device of claim 43, further comprises source and drain probing pads opened by photo-lithography and wet etching.
